(19) United States
(12) Patent Application Publication
(10) Pub. No.: US 2026/0089869 A1
(43) Pub. Date: Mar. 26, 2026

(54) LAPTOP COOLING VIA LOW-PRESSURE AIR MOVER

(71) Applicant: Intel Corporation, Santa Clara, CA (US)

(72) Inventors: Mark MacDonald, Beaverton, OR (US); Prakash Kurma Raju, Bangalore (IN); Kathiravan D, Bangalore (IN); Doddi Raghavendra, Bangalore (IN); Samarth Alva, Bangalore (IN); Krishnendu Saha, Bengaluru (IN)

(21) Appl. No.: 18/897,675

(22) Filed: Sep. 26, 2024

(51) Int. Cl. H05K 7/20

(52) U.S. Cl. CPC H05K 7/20145

(57) ABSTRACT

Technical solutions discussed herein include cooling systems for electronic devices, including low-pressure ionic blowers and electromagnetic air movers to improve thermal management in laptops. The cooling system may include multiple blower modules arranged in parallel or series configurations. The thermal solution may be a vapor chamber or a heat pipe, or may include a thin-film air-moving device integrated into an air gap. The cooling system may selectively operate between low pressure blower modules and centrifugal blowers based on cooling demands. The blower module may include an electrode configuration with a single exposed electrode. The cooling system may also incorporate an active noise cancellation system using phase-shifted signals between blower units.

### BACKGROUND

Improved cooling systems are needed for electronic devices (e.g., laptops) to deliver increased performance for a processor (e.g., central processing unit (CPU), graphics processing unit (GPU)). Some cooling systems include centrifugal cooling fans. However, these cooling systems often result in higher acoustic levels and limited cooling efficiency due to low flow rates and reliability issues in dusty or humid conditions. There is a need for electronic device cooling that can provide sufficient airflow at reduced acoustic levels and reduced power consumption.

### BRIEF DESCRIPTION OF THE DRAWINGS

In the drawings, which are not necessarily drawn to scale, like numerals may describe similar components in different views. Like numerals having different letter suffixes may represent different instances of similar components. Some embodiments are illustrated by way of example, and not limitation, in the figures of the accompanying drawings in which:

FIG. 1 illustrates a low pressure blower laptop cooling system design, according to an embodiment.

FIG. 2 shows a laptop cooling system comparison, according to an embodiment.

FIG. 3 shows a laptop cooling system, according to an embodiment.

FIG. 4 shows a pressure versus flow graph, according to an embodiment.

FIG. 5 shows a heat pipe laptop cooling system, according to an embodiment.

FIG. 6 shows a graph illustrating differential pressure (DP) in inches of water as a function of flow in cubic feet per minute (CFM), according to an embodiment.

FIG. 7 shows a laptop cooling system with vertical series-configured ionic wind blowers, according to an embodiment.

FIG. 8 shows a thin strip ionic air movement blower, according to an embodiment.

FIG. 9 shows a laptop cooling system with lateral series-configured thin strip blowers, according to an embodiment.

FIG. 10 shows a laptop cooling system with lateral series-configured thin strip blowers, according to an embodiment.

FIG. 11 shows a laptop cooling system with lateral series-configured thin strip blowers, according to an embodiment.

FIG. 12 shows a laptop cooling system with lateral series-configured thin strip blowers, according to an embodiment.

FIG. 13 shows a laptop cooling system with vertical series-configured thin strip blowers, according to an embodiment.

FIG. 14 shows a laptop hyperbaric architecture cooling system, according to an embodiment.

FIG. 15 shows a laptop hyperbaric architecture cooling system, according to an embodiment.

FIG. 16 shows an alternating current (AC) ionic air movement blower, according to an embodiment.

FIG. 17 shows a modular blower, according to an embodiment.

FIG. 18 shows a modular EM blower system, according to an embodiment.

FIG. 19A, representing the first view of a laptop keyboard, showcases a implementation of EM jet modules for cooling.

FIG. 19B, depicting the second view of a laptop keyboard, illustrates an alternative configuration of the EM jet modules.

FIG. 20 shows an EM jet air mover device assembly, according to an embodiment.

FIGS. 21A-21C show views of a laptop cooling jet thermal solution, according to an embodiment.

FIG. 22 is a flow diagram illustrating a method for cooling a computing device, according to an embodiment.

FIG. 23 is a block diagram illustrating a machine in the example form of a computer system, within which a set or sequence of instructions may be executed to cause the machine to perform any one of the methodologies discussed herein.

### DETAILED DESCRIPTION

To address problems facing traditional cooling systems, low-pressure ionic blower (e.g., air mover) devices may provide advantages over traditional fans by reducing or minimizing acoustic output and maintaining adequate cooling capacity. These low-pressure blower modules may be used to provide a fanless experience, improving overall usability of modern computing devices. These improved cooling solutions not only address limitations of existing cooling systems, but also pave the way for quieter and more efficient thermal solutions in increasingly compact electronic devices.

These improved cooling solutions may be implemented within a compact housing, which is designed to improve thermal management in increasingly compact computing devices. This cooling system uses low-pressure blowers to generate airflow through a carefully engineered path that reduces or minimizes resistance, thereby improving or optimizing cooling efficiency. The airflow path is configured with separate inlet and outlet ports that facilitate a low-resistance route, improving the effectiveness of heat dissipation. These cooling solutions may be integrated with a heat exchanger and/or with more complex thermal solutions (e.g., vapor chambers, heat pipes) that are thermally coupled to heat-generating components. The blower modules may be configured to be modular, which improves their ability to be implemented in various combinations of parallel configurations and series configurations to adapt to varying cooling demands. This modularity not only supports flexible design configurations, but also contributes to noise levels below 20 dBA, where noise levels below 20 dBA could be perceived as noiseless to the user.

These improved cooling solutions may include low-pressure blowers to facilitate airflow through a low-resistance path, improving or optimizing thermal management while maintaining noise levels below 20 dBA. The modular blower configuration allows for flexible arrangements, either in parallel or in series, to meet varying cooling demands. These solutions provide significant improvements in cooling capacity (e.g., ranging from 15 W to 25 W), while maintaining a reduced device profile (e.g., base thickness between 8 mm and 10 mm). These solutions also provide significant improvements in system impedance (e.g., resistance to airflow within an electronic device), which improves airflow and cooling efficiency by improving heat dissipation and removal. Furthermore, the compact nature of these solutions supports increased battery capacity and allows for thinner device profiles, making it ideal for newer and smaller computing devices. These improvements collectively contribute to a more efficient, adaptable, and user-friendly cooling solution.

These improved cooling solutions may include thin-film air-moving devices, which are particularly effective for targeted cooling in specific areas of an electronic device. These thin-film devices may be incorporated into one or more air gaps of the computing device, providing localized cooling without significantly altering the device form factor.

These improved cooling solutions may include an air mover that uses the movement of a diaphragm and electromagnetic coil under a magnetic field to create air flow. The movement of the coil and magnetic field is similar to the operation of a coil and magnetic field in a speaker; however, unlike the directional acoustic reproduction provided by a speaker diaphragm, the configuration of the diaphragm in the air mover is configured to create an airflow path.

These improved cooling solutions may be combined with centrifugal blowers, enabling selective operation based on cooling needs. This hybrid approach allows for efficient cooling during high-demand scenarios while maintaining a quiet operation during regular use. These cooling systems may be adaptable to different device form factors, including tablets and detachable systems, ensuring broad applicability across various computing devices. This flexibility in design and configuration provides improved thermal performance while accommodating diverse user requirements.

These solutions provide advantages over various alternative systems. In an example, the cooling AC ionic wind blower solutions described herein provide an airflow of 0.63 cubic feet per minute (CFM), acoustic levels of 12 dBA, and power consumption of 0.5 W. This provides improved acoustics relative to the 30-40 dBA of a piezo jet, improved airflow and acoustics relative to the 40-50 dBA and 0.25 CFM of a piezo jet with a smaller form factor, reduced power consumption relative to the another piezo jet operating at ultrasonic frequencies, and improved airflow and reduced power consumption of an ionic blower device employing DC high-voltage. This also provides improved reliability over other solutions that are affected by dust or humidity, such as the ionic blower devices employing relatively high DC voltage that often fail to operate in high dust or humid conditions.

In another example, the proposed electromagnetic (EM) jet cooling solutions described herein provide an airflow of 0.25 CFM, acoustic levels of 19 dBA, and power consumption of 0.2 W. These solutions provide improved acoustic and power performance relative to the 25 dBA and 1.2 W of another piezo jet operating at ultrasonic frequencies, relative to the 30-40 dBA and 0.5 W of a piezo jet, and relative to the 40-60 dBA and 0.25 W of a piezo jet with a smaller form factor. This also provides improved reliability and performance over other solutions that use a single port for inlet and outlet, such as a blower with a single port for inlet and outlet employing electromagnetic principles without noise cancellation.

In the following description, for purposes of explanation, numerous specific details are set forth to provide a thorough understanding of some example embodiments. It will be evident, however, to one skilled in the art that the present disclosure may be practiced without these specific details.

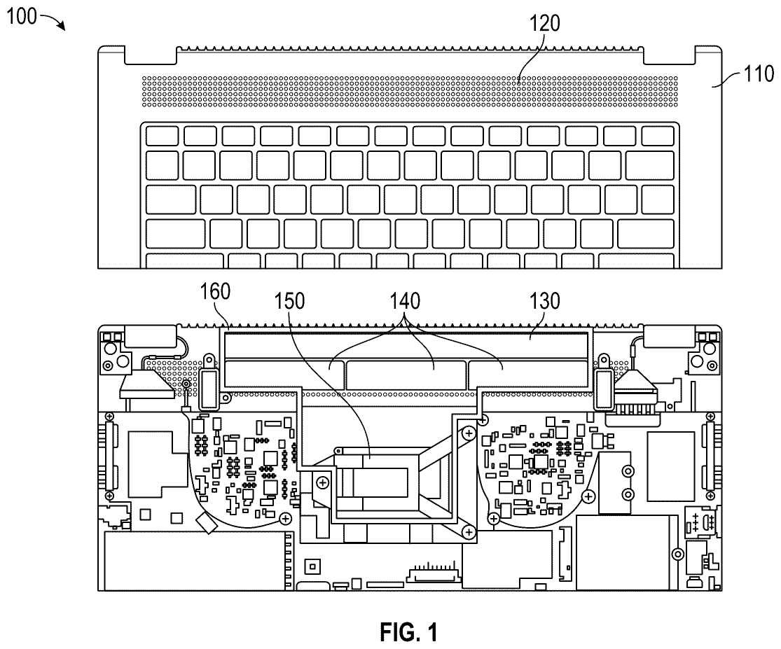

FIG. 1 illustrates a low pressure blower laptop cooling system design 100, according to an embodiment. FIG. 1 shows a laptop internal layout with a vapor chamber, according to an embodiment. The figure illustrates a cross-sectional view of a laptop, illustrating components of a cooling system design that includes low pressure blowers.

The C-cover 110 forms the top portion of the laptop chassis, typically including the keyboard and palm rest area. In this design, the C-cover incorporates the airflow inlet 120. This inlet is positioned to allow cool air to enter the laptop. The placement of the inlet on the C-cover side provides a low-resistance airflow path, providing improved performance while using low-pressure blowers.

The heat exchanger 130 may be near or adjacent to the airflow inlet 120 laptop. This heat exchanger 130 provides efficient transfer of heat away from internal components. The placement and design of the heat exchanger 130 work with the low-pressure blowers to provide improved heat dissipation.

The blower 140 provides improvements over alternative designs. Instead of a conventional fan, the system employs multiple smaller blowers or a single long blower positioned near or adjacent to the heat exchanger 130. These blowers are designed to operate at low pressure, providing sufficient airflow while maintaining low acoustic levels. The blowers draw in cool air from the inlet and direct it through the heat exchanger 130.

The alternating current (AC) ionic wind blower operates on the principle of electrohydrodynamics to generate airflow without moving parts. It consists of two main electrodes: an exposed electrode in direct contact with air and an embedded electrode separated by a dielectric material. When an alternating current is applied, it creates a strong electric field that ionizes air molecules near the exposed electrode. These charged particles are then repelled towards the embedded electrode, colliding with neutral air molecules and creating airflow. The alternating current may operate at a relatively low frequency, such as 500 Hz to 5 KHz. The alternating current may include an increased voltage level to improve ionization, such as 5-15 kilovolts. The use of AC causes the ions to oscillate, resulting in a bidirectional but net unidirectional airflow due to the asymmetric electrode configuration.

The AC ionic wind blower provides cooling while operating at sound levels at or below what a user perceives as substantially silent performance, such as noise levels at or below 20 dBA. The design may include multiple inlet and outlet openings positioned to synchronize airflow with electric field oscillations, enabling efficient air movement during both AC cycle phases. The blower may be constructed to be thin (e.g., 0.25-0.5 mm), allowing for modular designs that can be stacked or arranged to increase airflow or increase pressure capabilities. Unlike some alternative blower technologies, the design of this AC ionic wind blower' single exposed electrode helps reduce or prevent dust accumulation, improving long-term reliability.

This technology is particularly suitable for thin and light laptops where traditional fan-based cooling solutions may be impractical. Its silent operation, compact size, and potential for modular scaling offer significant advantages in thermal management for modern electronic devices, enabling efficient cooling in confined spaces.

The primary heat-generating component in the laptop may include a system on a chip (SOC), such as SOC 150, which typically includes a CPU. The SOC 150 is the main source of the heat that the cooling system is designed to manage. In an example, the SOC 150 may be positioned beneath the vapor chamber 160, which acts as a flat thermal solution that conveys heat away from the SOC 150 toward the heat exchanger 130.

The vapor chamber 160 provides further performance improvements of the thermal management system. The vapor chamber 160 may include a substantially flat, sealed container containing a thermally conductive liquid (e.g., water) that efficiently spreads heat from the SOC across the surface area of the vapor chamber 160. As the SOC generates heat, the heat causes liquid in the vapor chamber 160 to evaporate. This vapor then moves to cooler areas of the chamber where it condenses back into liquid, releasing its heat in the process. This cycle continues, effectively spreading the heat from the SOC 150 across the entire surface of the vapor chamber 160, which then transfers the heat to the heat exchanger 130 for dissipation.

The design of the low pressure blower laptop cooling system design 100 provides improved cooling capabilities with reduced cooling system volume while maintaining low acoustic levels, addressing the challenge of delivering high processor performance in increasingly small devices. By reducing or eliminating a traditional fan cut-out in the motherboard design, the low pressure blower laptop cooling system design 100 provides for more space for other components (e.g., a larger battery), further improving the overall laptop design.

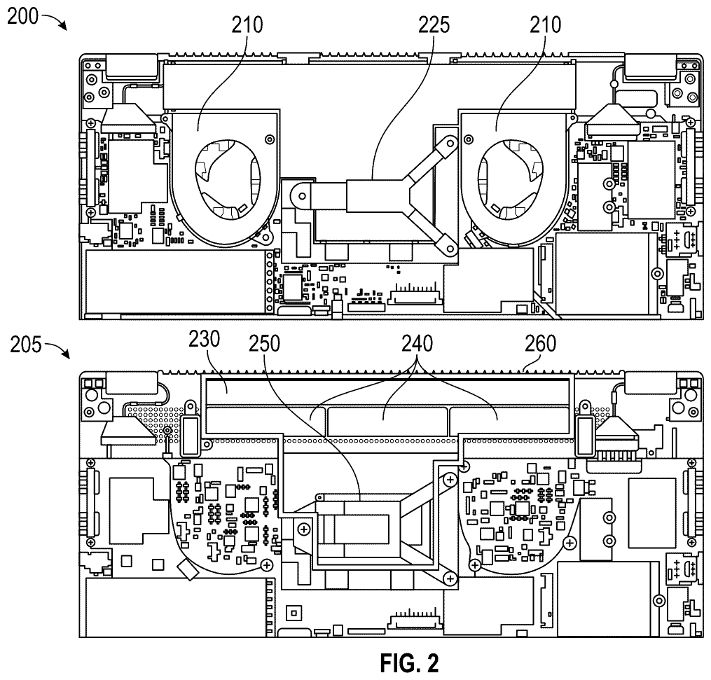

FIG. 2 shows a laptop cooling system comparison, according to an embodiment. FIG. 2 illustrates a first laptop cooling system 200 and a second laptop cooling system 205. The first laptop cooling system 200 includes a centrifugal blower 210, which may include a traditional centrifugal blower cooling component found in laptop designs. The first laptop cooling system 200 may include a first SOC 225, which generates heat within the laptop. This centrifugal blower 210 is typically positioned near the rear of the laptop and is responsible for drawing in cool air and expelling heated air from the system. The centrifugal blower 210 operates at higher pressures compared to the low-pressure blowers, but it also requires more power, requires more laptop space, and generates more noise.

Also illustrated in FIG. 2 is a second laptop cooling system 205. The second laptop cooling system 205 includes a second SOC 250, which also generates heat within the laptop. A heat exchanger 230 may be positioned near the hinge area of the laptop. The heat exchanger 230 may be configured to transfer heat away from the second SOC 250 and other internal components.

The second laptop cooling system 205 may include low-pressure blowers 240. These low-pressure blowers 240 are smaller and are arranged in a series or parallel configuration, depending on the specific cooling requirements. The low-pressure blowers 240 are designed to operate at lower pressures than the centrifugal blower, providing sufficient airflow while maintaining significantly lower acoustic levels. The low-pressure blowers 240 are positioned to create a low-resistance airflow path, improving the overall cooling efficiency of the system. An airflow outlet 260 may be located at the rear of the laptop, allowing the heated air to exit the system after passing through the heat exchanger 230 and over the components. The second laptop cooling system 205 is designed to expel hot air efficiently from the laptop, maintaining desired internal temperatures and reducing or preventing heat recirculation.

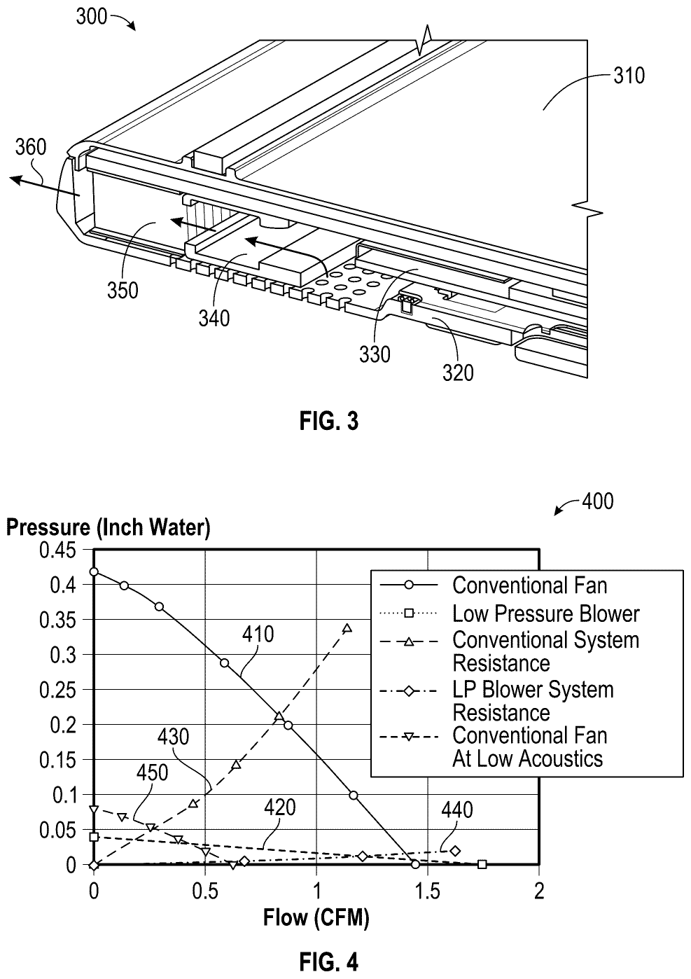

FIG. 3 shows laptop cooling system 300, according to an embodiment. This figure illustrates a cross-sectional view, showing various components of an improved cooling system design. The laptop cooling system 300 is shown with the laptop chassis inverted, where the D-cover 310 (e.g., laptop bottom cover) is on the upper portion of the laptop cooling system 300 as shown in FIG. 3. In this design, the D-cover 310 may include ventilation features to facilitate airflow and heat dissipation.

The C-cover 320 (e.g., keyboard cover) houses the keyboard and palm rest area. In this improved design, the C-cover incorporates an airflow inlet positioned on the forehead of the system. This inlet allows cool air to enter the laptop, creating a low-resistance airflow path for the airflow generated by the low-pressure blowers.

The motherboard 330 is the main circuit board of the laptop, hosting various processing components (e.g., SOC, CPU, GPU). The motherboard 330 layout may be configured to accommodate the cooling system, potentially eliminating a vacant space for a traditionally large centrifugal fan and allowing for more efficient use of internal laptop chassis space.

Instead of a centrifugal fan, the laptop cooling system 300 includes one or more low-pressure blower modules 340 system near the heat exchanger. These low-pressure blower modules 340 are designed to operate at low pressure, providing sufficient airflow while maintaining low acoustic levels. The low-pressure blower modules 340 draw in cool air from the inlet on the C-cover 320 and direct it through the heat exchanger 350.

The heat exchanger 350 may be positioned near the hinge area of the laptop. This heat exchanger 350 is designed to efficiently transfer heat from the internal components out of the laptop chassis. Its placement and design are optimized to work in conjunction with the low-pressure blower modules 340, ensuring effective heat dissipation.

The airflow outlet 360 is located at the rear of the laptop, allowing the heated air to exit the system after passing through the heat exchanger. The placement of the outlet at the rear of the device helps direct the warm air out of the laptop and away from the user.

FIG. 4 shows pressure versus flow graph 400, according to an embodiment. This pressure versus flow graph 400 illustrates the performance characteristics of various cooling solutions and system designs for laptop thermal management.

The conventional laptop fan performance 410 is represented by a curve that shows higher pressure capabilities compared to the low-pressure blower. This curve demonstrates that traditional fans can generate higher static pressure, allowing them to overcome greater system resistance. However, this higher pressure capability often comes at the cost of increased noise levels.

The low pressure blower performance 420 is depicted by a curve that shows lower maximum pressure but potentially higher maximum flow rates compared to a conventional fan. This curve represents the low-pressure blower technology, which is designed to operate efficiently at lower pressures while maintaining adequate airflow, providing cooling at reduced acoustic levels.

The conventional laptop fan resistance 430 is illustrated as a steeper curve, indicating higher system impedance. This curve represents the resistance to airflow in a typical laptop design, where air must navigate through various components and narrow passages before being expelled. The steeper slope suggests that conventional designs require higher pressure to achieve desired flow rates.

The low pressure blower resistance 440 is shown as a flatter curve, representing the reduced system impedance achieved through the design. This lower resistance is a result of the improved airflow path, including the strategically placed C-cover inlet and the minimized obstructions between the inlet and outlet. The flatter curve allows the low-pressure blower to achieve higher flow rates at lower pressures, improving cooling efficiency.

The conventional laptop fan 450 is depicted as a scaled-down version of the original fan curve, representing its performance at a lower acoustic level. This curve demonstrates that when a conventional fan is operated at noise levels comparable to the low-pressure blower (e.g., around 12 dBA), its performance is significantly reduced. The intersection of this curve with the system resistance curve results in much lower airflow compared to both the full-speed conventional fan and the low-pressure blower system.

Flow graph 400 illustrates advantages of the proposed low-pressure blower system. By reducing system impedance and using blowers optimized for low-pressure operation, the design achieves comparable or superior cooling performance to conventional fans while maintaining significantly lower noise levels. This balance of performance and acoustics addresses the challenge of delivering effective cooling in thin and light laptop designs without compromising on user experience.

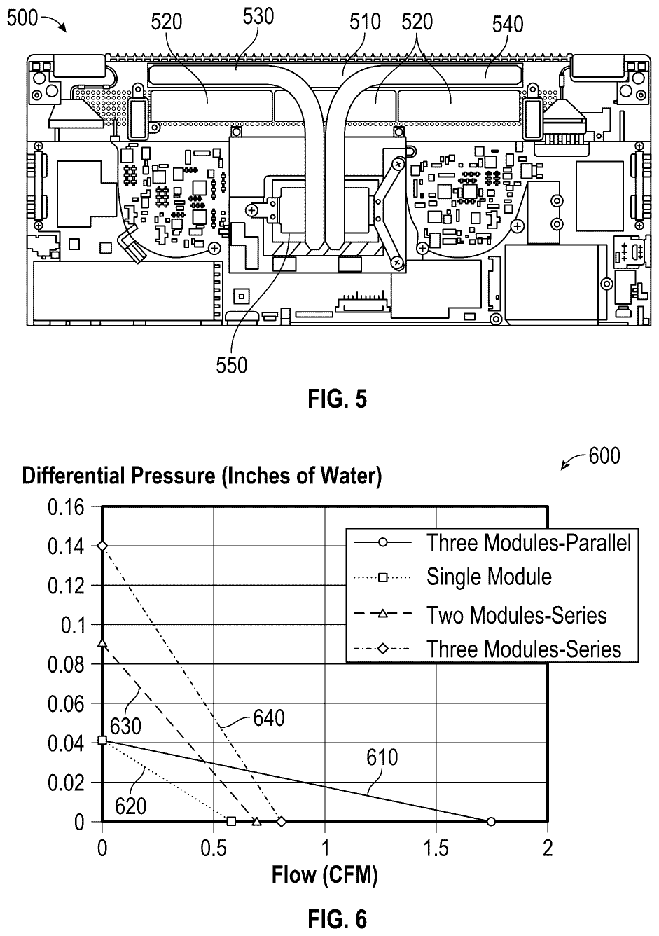

FIG. 5 shows a heat pipe laptop cooling system 500, according to an embodiment. Heat pipe laptop cooling system 500 illustrates an alternative cooling solution for thin and light laptops, using heat pipes instead of a vapor chamber for thermal management.

The heat exchanger 510 may be positioned near the hinge area of the laptop, similar to the vapor chamber design. The heat exchanger 510 is designed to transfer heat efficiently from the internal components to the airflow. Its placement is optimized to work in conjunction with the low-pressure blowers, providing improved heat dissipation.

The heat pipe laptop cooling system 500 includes low-pressure blowers 520. Instead of a larger centrifugal fan, the heat pipe laptop cooling system 500 includes multiple smaller low-pressure blowers 520 or a single long blower placed near or adjacent to the heat exchanger 510. These low-pressure blowers 520 are designed to operate at low pressure, providing sufficient airflow while maintaining low acoustic levels. The blowers draw in cool air from an inlet on the C-cover and direct it through the heat exchanger 510.

The heat pipe laptop cooling system 500 may include a first heat pipe 530 and a second heat pipe 540. These heat pipes may include sealed tubes containing a small amount of liquid (e.g., water) that transport heat efficiently from one end to the other. In heat pipe laptop cooling system 500, the heat pipes are arranged in an L-shaped configuration, with one end in contact with the heat-generating SOC 550 and the other end connected to the heat exchanger 510. As the SOC 550 generates heat, it causes the liquid in the heat pipes to evaporate.

This vapor then moves to the cooler end of the heat pipe where it condenses back into liquid, releasing its heat to the heat exchanger 510. This cycle continues, effectively transporting heat from the SOC 550 to the heat exchanger 510 for dissipation.

This heat pipe laptop cooling system 500 design provides high cooling capabilities in thin and light systems while maintaining low acoustic levels. By using heat pipes instead of a vapor chamber, this heat pipe laptop cooling system 500 offers an alternative approach to thermal management that may be more suitable for certain laptop configurations or manufacturing processes. The combination of first heat pipe 530, second heat pipe 540, and heat exchanger 510 addresses the challenge of delivering high performance in devices with limited thickness, potentially allowing for more flexible internal layouts and improved overall laptop design.

FIG. 6 shows pressure graph 600 showing differential pressure as a function of airflow, according to an embodiment. Pressure graph 600 shows the DP in inches of water as a function of airflow in cubic feet per minute (CFM) for four different low-pressure blower configurations: three parallel blower modules 610, a single blower module 620, two series blower modules 630, and three series blower modules 640.

The curve for three parallel blower modules 610 shows the highest maximum flow rate among all configurations. This arrangement allows for the greatest volume of air movement but at relatively lower pressure levels. The parallel configuration combines the flow rates of individual modules while maintaining a pressure similar to a single blower module 620, making it suitable for applications requiring high airflow in low-impedance systems.

The curve for single blower module 620 represents the baseline performance of an individual low-pressure blower module. This curve shows the lowest maximum flow rate and pressure among all configurations, serving as a reference point for understanding the benefits of multi-module arrangements.

The curve for two series blower modules 630 demonstrates an increase in pressure capabilities compared to single blower module 620, while also showing a moderate increase in flow rate. This configuration stacks two modules in series, effectively increasing the pressure head by combining the pressure capabilities of both modules. The series arrangement is beneficial for overcoming higher system impedances while still providing improved flow rates over a single blower module 620.

The curve for three series blower modules 640 exhibits the highest pressure capabilities among all configurations, along with a further increase in flow rate compared to two series blower modules 630. This arrangement stacks three modules vertically, maximizing the pressure head and allowing for effective cooling in high-impedance systems. The three series blower modules 640 provides a balance of increased pressure and flow rate, making it suitable for applications requiring both high pressure and substantial airflow.

This graph effectively illustrates the flexibility and scalability of the low-pressure blower modules. By arranging the modules in different configurations, the cooling system configuration can be designed for various laptop designs and thermal requirements. For example, the parallel configuration may be preferred for maximizing airflow in low-impedance systems, while the series configurations may be better suited for overcoming higher system resistances. This adaptability allows for tailored cooling solutions that can address the specific thermal management needs of different laptop models, enabling more efficient and quieter cooling systems in thin and light devices.

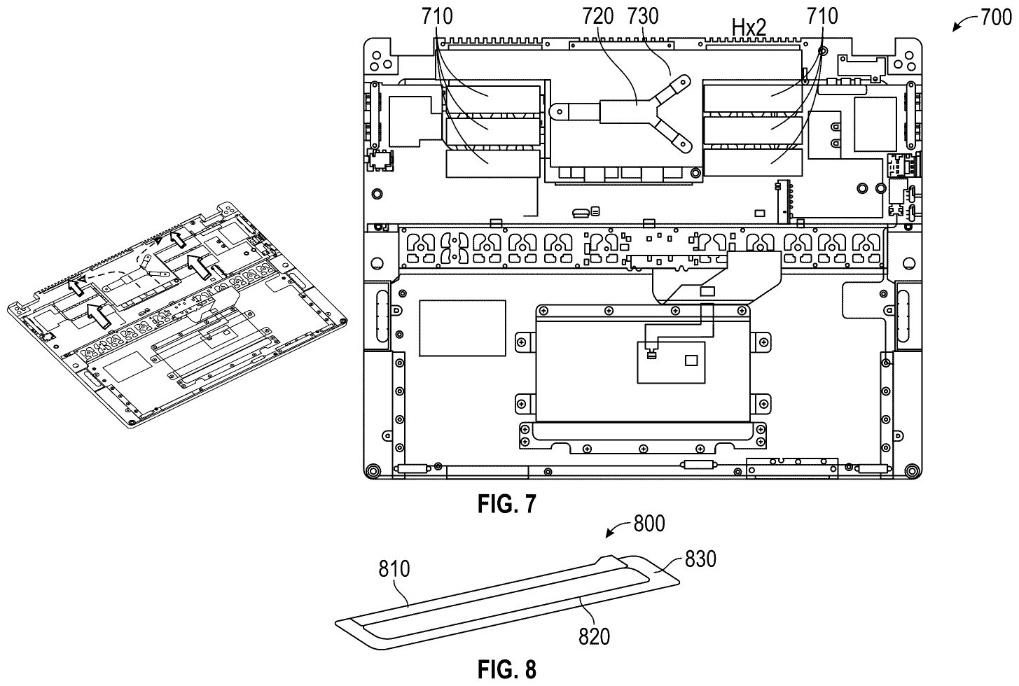

FIG. 7 shows a laptop cooling system 700 with vertical series-configured ionic wind blowers, according to an embodiment. This figure illustrates an improved approach to thermal management in laptops, using ionic wind blowers arranged vertically in series to improve cooling performance.

As shown in FIG. 7, the ionic wind blowers 710 may be arranged vertically (e.g., in series), such as to create a multi-stage air mover. This configuration allows for increased pressure capabilities while maintaining the low acoustic levels characteristic of ionic wind technology. By arranging the blowers in series, the system can overcome higher impedances typically found in laptop cooling systems, potentially enabling more efficient cooling in compact form factors.

The SOC 720 is positioned beneath the vapor chamber thermal solution 730. The SOC 720 is the primary heat-generating component in the laptop, and the vapor chamber thermal solution 730 spreads the heat generated by the SOC 720 across the surface area of the vapor chamber thermal solution 730. As the SOC 720 generates heat, the heat causes the liquid in the vapor chamber thermal solution 730 to evaporate. This vapor then moves to cooler areas of the chamber where it condenses back into liquid, releasing its heat in the process, which then transfers the heat to the vertically arranged ionic wind blowers 710 for dissipation.

This improved cooling system design provides higher cooling capabilities in thin and light systems while maintaining low acoustic levels. By using vertically arranged ionic wind blowers in conjunction with a vapor chamber, the design addresses the challenge of delivering high performance in devices with limited thickness. The vertical configuration of the blowers potentially allows for more efficient use of internal space, while the ionic wind technology enables quiet operation. This combination could result in improved thermal management and overall performance in compact laptop form factors.

FIG. 8 shows a thin strip ionic air movement blower 800, according to an embodiment. FIG. 8 illustrates an improved approach to air movement in laptop cooling systems, using the principles of ionic wind generation in a compact, thin strip format.

The exposed electrode 810 is positioned on one side of the device and is directly exposed to the air. When energized, the exposed electrode 810 ionizes nearby air molecules, creating charged particles that are then repelled towards the embedded electrode. The exposed nature of this exposed electrode 810 allows for direct interaction with the surrounding air, initiating the ionic wind effect.

An embedded electrode 820 is positioned within the device, separated from the exposed electrode 810 by a dielectric material 830. This embedded electrode 820 is not directly exposed to the air but creates an electric field for ionic wind generation. The embedded design of this thin strip ionic air movement blower 800 helps to prevent dust accumulation and improve the overall reliability of the device, addressing some of the challenges faced by previous ionic wind technologies.

The thin strip ionic air movement blower 800 represents the entire assembly, combining the exposed electrode 810, embedded electrode 820, and dielectric material 830 into a compact, low-profile device. This thin strip ionic air movement blower 800 is designed to be extremely thin, with a thickness ranging from 0.25 to 0.5 mm, allowing for integration into the limited spaces available in modern thin and light laptops. The thin strip design enables flexible placement options within the laptop chassis, such as in the air gap between the keyboard and C-cover or between the thermal solution and D-cover.

This improved air mover operates on the principle of electrohydrodynamics, creating airflow without requiring moving parts. When a high voltage (e.g., 5-15 kilovolts) at AC frequencies of 500 Hz to 5 KHz is applied between the exposed electrode 810 and embedded electrode 820, the high voltage creates an electric field that ionizes air molecules near the exposed electrode 810. These charged particles are then accelerated towards the embedded electrode 820, colliding with neutral air molecules along the way and creating a net airflow. This mechanism allows for silent operation and potentially lower power consumption compared to traditional fan-based cooling solutions.

The thin strip ionic air movement blower 800 offers several advantages for laptop thermal management. The thin profile allows for integration into areas where traditional fans may not be able to fit, potentially enabling more efficient use of internal space in laptops. The operation of this technology appears silent to a user, which provides improved user experience, especially in noise-sensitive environments. Additionally, the ability to create airflow without moving parts may increase reliability and longevity of the cooling system.

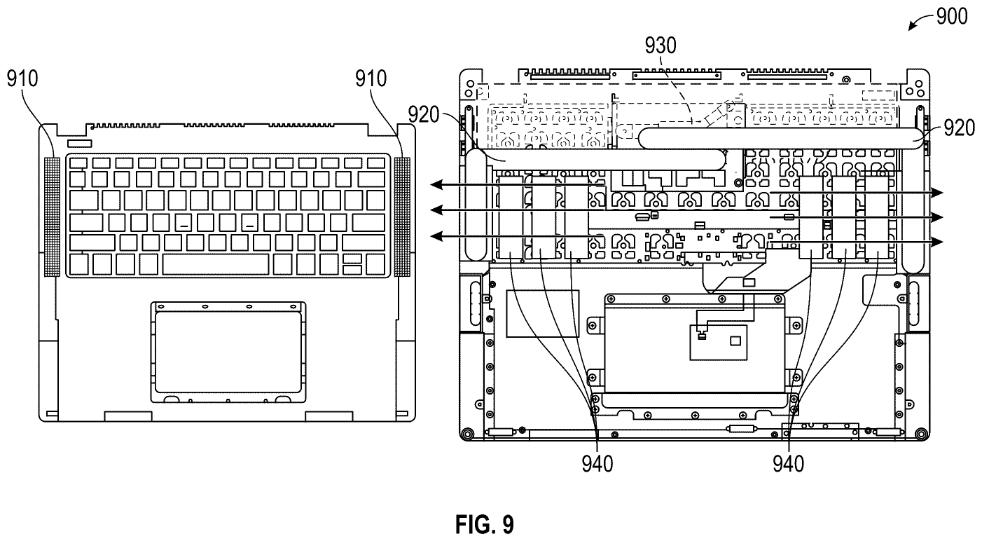

FIG. 9 shows a laptop cooling system with lateral series-configured thin strip blowers 900, according to an embodiment. FIG. 9 illustrates an improved approach to thermal management in laptops, using thin-strip AC ionic wind blowers 940 arranged laterally in series to improve cooling performance while maintaining a low profile.

The C-cover airflow inlets 910 are strategically positioned to allow cool air to enter the system from both sides of the keyboard area. This configuration creates a low-resistance airflow path, which improves the airflow through the low-pressure characteristics of the thin-strip AC ionic wind blowers 940. By drawing air from the sides, this design potentially reduces the need for bottom or rear inlets, allowing for a more streamlined laptop chassis.

The heat pipes 920 transfer heat efficiently from the SOC 930 to the cooling heat pipes 920. These heat pipes 920 are arranged in an L-shaped configuration, with one end in contact with the heat-generating SOC 930 and the other end between the thin-strip AC ionic wind blowers 940 and outlet ports.

The lateral series-configured thin-strip AC ionic wind blowers 940 are arranged in series along the sides of the laptop. This configuration allows for increased airflow capabilities while maintaining a thin profile. The series arrangement of the thin-strip AC ionic wind blowers 940 enables them to overcome higher system impedances, allowing for more efficient cooling in compact form factors. Each of the thin-strip AC ionic wind blowers 940 operates by creating an electric field between exposed and embedded electrodes, ionizing air molecules and generating airflow without requiring any moving parts. This mechanism allows for silent operation and potentially lower power consumption compared to traditional fan-based cooling solutions.

This lateral series configuration of thin-strip AC ionic wind blowers 940 offers several advantages for laptop thermal management. The thin profile of the blowers allows for integration into areas where traditional fans may not be able to fit, enabling more efficient use of internal space in laptops. The silent operation of this technology improves user experience, especially in noise-sensitive environments. Additionally, the ability to create airflow without moving parts increases reliability and longevity of the cooling system.

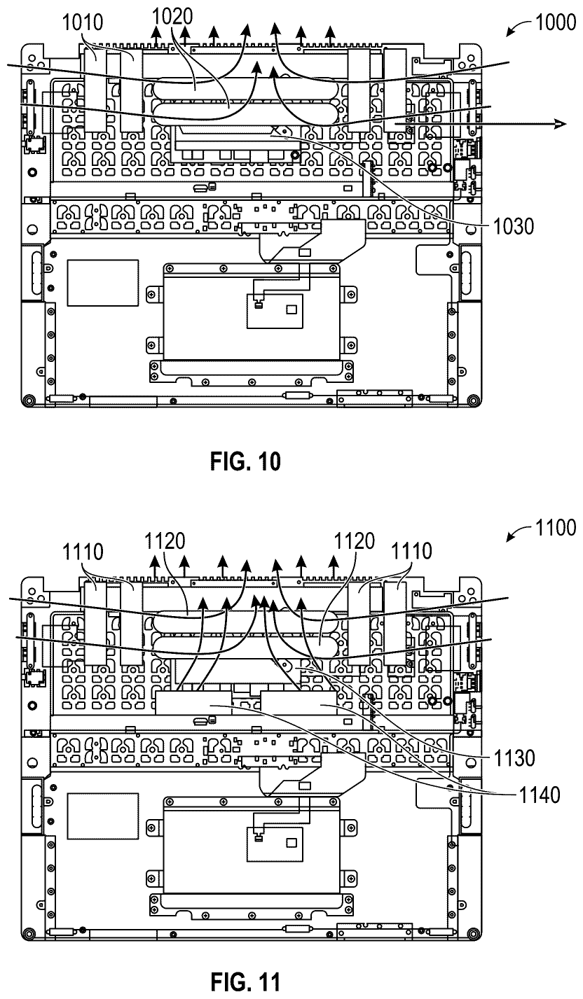

FIG. 10 shows laptop cooling system 1000 with lateral series-configured thin strip blowers, according to an embodiment. FIG. 10 illustrates an improved approach to thermal management in laptops, using AC ionic wind blowers 1010 arranged laterally in series to improve cooling performance while maintaining a low profile.

The series-configured thin strip blowers 1010 are arranged in series along the sides of the laptop. The heat pipes 1020 transfer heat from the SOC 1030 to the cooling system AC ionic wind blowers 1010. The lateral series arrangement of AC ionic wind blowers 1010 may pull air in from vents on the sides of the laptop chassis or on the sides of the keyboard (e.g., C-cover airflow inlets 910 shown in FIG. 9) and direct air across the heat pipes 1020 and out of the back of the laptop.

This lateral series configuration allows for increased airflow capabilities while maintaining a thin profile, with each blower potentially as thin as 0.25 to 0.5 lateral mm. The series arrangement of the blowers enables them to overcome higher system impedances, potentially allowing for more efficient cooling in compact form factors. The thin profile of the blowers allows for integration into areas where traditional fans cannot fit, potentially enabling more efficient use of internal space in laptops.

FIG. 11 shows laptop cooling system 1100 with thin strip blowers in parallel and series configurations, according to an embodiment. FIG. 11 illustrates an alternative improved approach to thermal management in laptops, combining lateral and vertical AC ionic wind blowers to improve cooling performance while maintaining a low profile.

As shown in FIG. 11, the laptop cooling system 1100 includes series-configured thin strip blowers 1110 that are arranged in series along the sides of the laptop. The laptop cooling system 1100 further includes parallel-configured thin strip blowers 1140 that are arranged behind the heat pipes 1120.

The heat pipes 1120 transfer heat from the SOC 1130 to the AC ionic wind blowers 1110 and parallel-configured thin strip blowers 1140. The lateral series arrangement of AC ionic wind blowers 1110 may pull air in from vents on the sides of the laptop chassis or on the sides of the keyboard and direct air across the heat pipes 1120 and out of the back of the laptop. Similarly, the parallel-configured thin strip blowers 1140 may pull air in from laptop vents and direct air across the heat pipes 1120 and out of the back of the laptop.

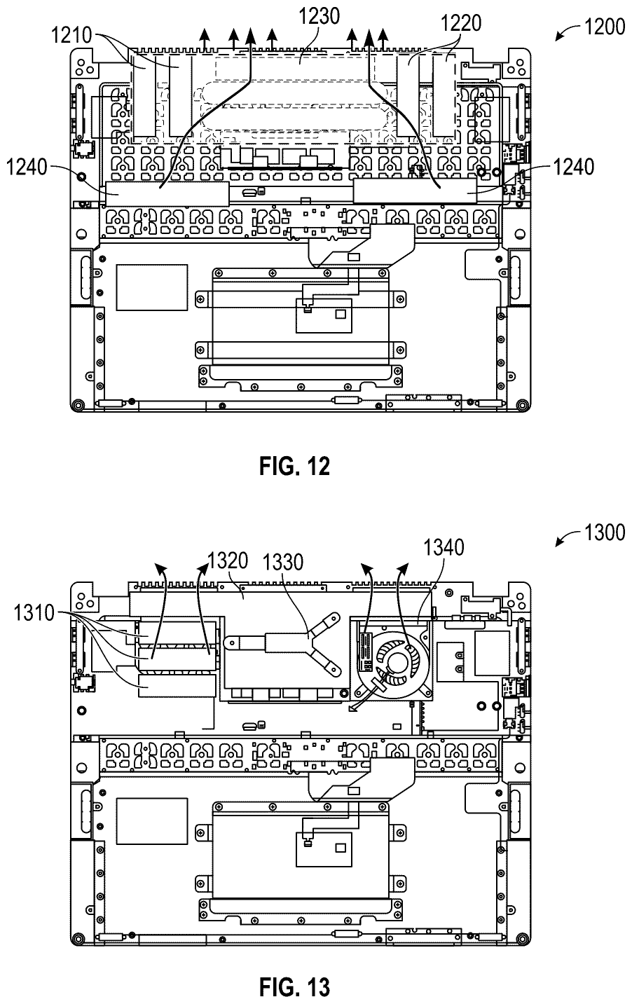

FIG. 12 shows laptop cooling system 1200 with lateral series-configured thin strip blowers, according to an embodiment. FIG. 12 illustrates an improved approach to thermal management in laptops, using AC ionic wind blowers 1220 arranged laterally in series along with a heat exchanger 1230 to improve cooling performance while maintaining a low profile.

The lateral series-configured thin strip blowers 1210 and 1220 are arranged on both sides of the heat exchanger 1230. The series arrangement of the series-configured thin strip blowers 1210 and 1220 enables them to overcome higher system impedances, potentially allowing for more efficient cooling in compact form factors.

The series-configured thin strip blowers 1210 and 1220 generate an airflow from D-cover inlets 1240 past the heat exchanger 1230 and out of the rear of the laptop. The heat exchanger 1230 is designed to efficiently transfer heat from the heat-generating internal components to the airflow generated by the series-configured thin strip blowers 1210 and 1220. The D-cover inlet 1240 may be positioned on the bottom cover of the laptop to allow cool air to enter the system, which further reduces the resistance of the airflow path, more effectively using the low-pressure characteristics of the series-configured thin strip blowers 1210 and 1220. By drawing air from the D-cover inlet 1240, this laptop cooling system 1200 potentially allows for a more streamlined laptop chassis while still providing efficient cooling.

FIG. 13 shows hybrid laptop cooling system 1300, according to an embodiment. FIG. 13 illustrates an improved approach to thermal management in laptops, combining vertical AC ionic wind blowers 1310 with a centrifugal blower 1340 to provide improved and selectable cooling performance while maintaining a low profile.

The thermal solution 1320 (e.g., vapor chamber), spreads the heat generated by the SOC 1330 across its surface area. One or more of the vertical AC ionic wind blowers 1310 and the centrifugal blower 1340 may generate airflow across the thermal solution 1320 and out of the laptop chassis. As shown in FIG. 13, the centrifugal blower 1340 blows air directly toward the back of the laptop and out of rear vents of the laptop chassis.

The vertical series-configured thin strip blowers 1310 may be stacked vertically to create a multi-stage air mover. This configuration allows for increased pressure capabilities while maintaining the low acoustic levels. The vertical arrangement of these blowers enables them to overcome higher impedances typically found in laptop cooling systems, potentially allowing for more efficient cooling in compact form factors.

The centrifugal blower 1340 represents a cooling element in this hybrid design. This centrifugal blower 1340 may be configured to work with the thin strip blowers, potentially activating during high-power tasks such as gaming or video content creation. The centrifugal blower 1340 can provide additional airflow when needed, complementing the constant, low-noise operation of the thin strip blowers. This hybrid approach allows for a fanless experience during most common tasks while still providing the capability for increased cooling during demanding workloads.

The design of this improved hybrid laptop cooling system 1300 provides higher cooling capabilities in thin and light systems while maintaining low acoustic levels for most usage scenarios. By combining vertical AC ionic wind blowers 1310 with a centrifugal blower 1340, the design addresses the challenge of delivering high performance across various workloads in devices with limited thickness. The silent operation of the vertical AC ionic wind blowers 1310 improves user experience during common tasks, while the centrifugal blower 1340 provides additional cooling capacity for demanding applications.

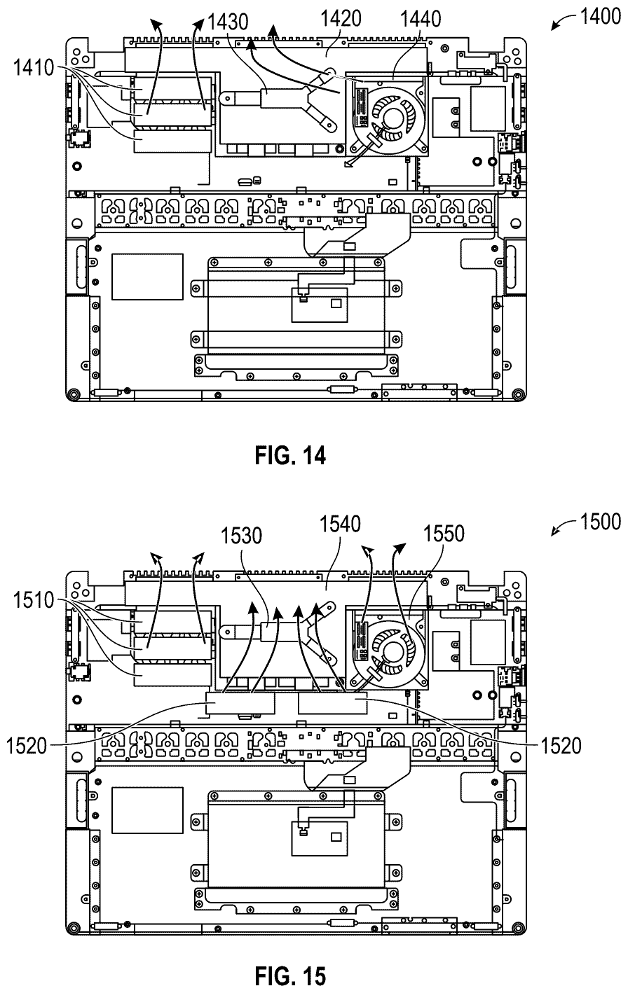

FIG. 14 shows laptop hyperbaric architecture cooling system 1400, according to an embodiment. FIG. 14 illustrates an improved approach to thermal management in laptops, combining vertical AC ionic wind blowers 1410 with a centrifugal blower 1440 in a hyperbaric configuration to improve cooling performance while maintaining a low profile. In a hyperbaric architecture used by laptop hyperbaric architecture cooling system 1400, the system is pressurized by adding gaskets around the fan, thermal solution, and inlet areas. This pressurization creates a higher pressure within the cooling area compared to the rest of the system.

Similar to the hybrid laptop cooling system 1300, the laptop hyperbaric architecture cooling system 1400 includes a thermal solution 1420 that spreads the heat generated by the SOC 1430 across its surface area. One or more of the vertical AC ionic wind blowers 1410 and the centrifugal blower 1440 may generate airflow across the thermal solution 1420 and out of the laptop chassis. As shown in FIG. 14, the centrifugal blower 1440 blows air toward the thermal solution 1420 and out of rear vents of the laptop chassis.

The vertical series-configured thin strip blowers 1410 may be stacked vertically to create a multi-stage air mover. This configuration allows for increased pressure capabilities while maintaining the low acoustic levels. The vertical arrangement of these blowers enables them to overcome higher impedances typically found in laptop cooling systems, potentially allowing for more efficient cooling in compact form factors.

The centrifugal blower 1440 may be configured to work with the thin strip blowers, potentially activating during high-power tasks such as gaming or video content creation. The centrifugal blower 1440 can provide additional airflow when needed, complementing the constant, low-noise operation of the thin strip blowers. This hybrid approach allows for a fanless experience during most common tasks while still providing the capability for increased cooling during demanding workloads.

This improved hyperbaric cooling system design provides higher cooling capabilities in thin and light systems while maintaining low acoustic levels for most usage scenarios. By combining vertical AC ionic wind blowers 1410 with a centrifugal blower 1440 in a pressurized environment, the design addresses the challenge of delivering high performance across various workloads in devices with limited thickness. The silent operation of the thin strip blowers improves user experience during common tasks, while the centrifugal blower provides additional cooling capacity for demanding applications. The hyperbaric architecture further improves cooling efficiency by creating a pressurized environment around the heat-generating components.

FIG. 15 shows laptop hyperbaric architecture cooling system 1500, according to an embodiment. FIG. 15 illustrates an improved approach to thermal management in laptops, combining vertical AC ionic wind blowers 1510 and horizontal AC ionic wind blowers 1520 with a centrifugal blower 1550 in a hyperbaric configuration to improve cooling performance while maintaining a low profile.

The centrifugal blower 1550 includes a thermal solution 1540 that spreads the heat generated by the SOC 1530 across its surface area. One or more of the vertical AC ionic wind blowers 1510, the horizontal AC ionic wind blowers 1520, and the centrifugal blower 1550 may generate airflow across the thermal solution 1540 and out of the laptop chassis.

The vertical series-configured thin strip blowers 1510 are stacked vertically to create a multi-stage air mover. This configuration allows for increased pressure capabilities while maintaining the low acoustic levels characteristic of ionic wind technology. The vertical arrangement of these blowers enables them to overcome higher impedances typically found in laptop cooling systems, potentially allowing for more efficient cooling in compact form factors.

The horizontal AC ionic wind blowers 1520 are positioned along the sides of the laptop, potentially in the air gap between the keyboard and C-cover or between the thermal solution and D-cover. The parallel configuration of these horizontal AC ionic wind blowers 1520 allows for increased airflow across a wider area, potentially improving the overall cooling efficiency of the system. The vertical AC ionic wind blowers 1510 and the horizontal AC ionic wind blowers 1520 operate on the same ionic wind principle, providing silent and efficient air movement in a compact form factor.

The centrifugal blower 1550 is positioned to work in conjunction with the thin strip blowers, activating during high-power tasks such as gaming or content creation. The centrifugal blower can provide additional airflow when needed, complementing the constant, low-noise operation of the thin strip blowers. This hybrid approach allows for a fanless experience during most common tasks while still providing the capability for increased cooling during demanding workloads.

This improved laptop hyperbaric architecture cooling system 1500 design provides higher cooling capabilities in thin and light systems while maintaining low acoustic levels for most usage scenarios. By combining vertical AC ionic wind blowers 1510, horizontal AC ionic wind blowers 1520, and centrifugal blower 1550 in a pressurized environment, the design addresses the challenge of delivering high performance across various workloads in devices with limited thickness. The silent operation of the thin strip blowers improves user experience during common tasks, while the centrifugal blower 1550 provides additional cooling capacity for demanding applications. The hyperbaric architecture further improves cooling efficiency by creating a pressurized environment around the heat-generating components.

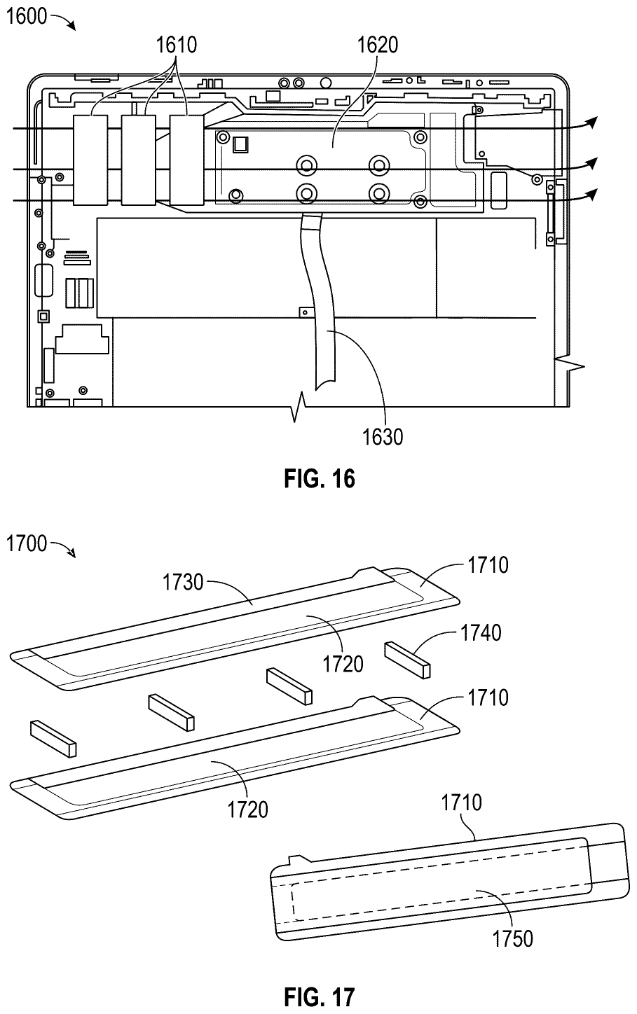

FIG. 16 shows AC ionic air movement blower 1600, according to an embodiment. FIG. 16 illustrates an improved approach to thermal management in tablet form factor devices, using AC ionic air movement blowers to improve cooling performance while maintaining a low profile.

The AC ionic air movement blower modules 1610 are arranged in a multi-stage configuration to increase the overall airflow and pressure capabilities. This arrangement allows for efficient cooling in the compact space of a tablet device. The AC ionic air movement blower modules 1610 may operate silently, improving user experience and reducing noise levels. The design of this AC ionic air movement blower 1600 may include multiple inlet and outlet openings to create airflow.

The heat exchanger 1620 (e.g., thermal solution), is positioned to efficiently transfer heat from the internal components to the airflow generated by the AC ionic air movement blower modules 1610. This heat exchanger 1620 may be formed as a thin, flat, and thermally conductive component designed to maximize heat dissipation within the limited space of a tablet form factor. It may be made of materials with high thermal conductivity, such as copper or aluminum, to provide improved heat transfer.

A thermal conduit 1630 provides improved performance, including transferring heat from the heat-generating components, such as a SOC or other processor, to the heat exchanger 1620. This thermal conduit 1630 may be in the form of heat pipes or a vapor chamber, efficiently spreading the heat across the surface area of the heat exchanger 1620. As the heat-generating components generate heat, it causes the liquid within the thermal conduit to evaporate. This vapor then moves to the cooler areas near the heat exchanger 1620 where it condenses back into liquid, releasing its heat. This cycle continues, effectively transporting heat from the heat-generating components to the heat exchanger 1620 where it can be dissipated by the AC ionic air movement blower modules 1610.

This improved cooling system design provides higher cooling capabilities in tablet form factor devices while maintaining low acoustic levels. By using AC ionic air movement blowers, the design addresses the challenge of delivering high performance in tablets and other devices with very limited thickness. The silent operation of this technology contributes to improved user experience, especially in noise-sensitive environments. Additionally, the ability to create airflow without moving parts may increase reliability and longevity of the cooling system, which is particularly beneficial in the compact and often sealed environments of tablet devices.

FIG. 17 shows modular blower 1700, according to an embodiment. FIG. 17 illustrates an improved approach to air movement in laptop cooling systems, using the principles of ionic wind generation in a compact, stackable format. Multiple thin strip ionic air movement blowers 1710 may be stacked and separated by one or more separators 1740.

Each thin strip ionic air movement blower 1710 is designed to be thin (e.g., 0.25 to 0.5 mm), allowing for integration into the limited spaces available in modern thin and light laptops. The thin strip design enables flexible placement options within the laptop chassis, such as in the air gap between the keyboard and C-cover or between the thermal solution and D-cover. This blower operates on the principle of electrohydrodynamics, creating airflow without any moving parts.

Each thin strip ionic air movement blower 1710 includes an embedded electrode 1720 that is positioned within the device, separated from the exposed electrode by a dielectric material. This embedded electrode 1720 is not directly exposed to the air but creates the electric field necessary for ionic wind generation. The embedded design of this electrode helps to prevent dust accumulation and improve the overall reliability of the device, addressing some of the challenges faced by previous ionic wind technologies.

Each thin strip ionic air movement blower 1710 further includes an exposed electrode 1730. Each exposed electrode 1730 is positioned on one side of the thin strip ionic air movement blower 1710 and is directly exposed to the air. When energized, it ionizes nearby air molecules, creating charged particles that are then repelled towards the embedded electrode. The exposed nature of this electrode allows for direct interaction with the surrounding air, initiating the ionic wind effect.

Each separator 1740 may include an insulating material with high dielectric strength, such as a polymer or plastic. Each separator 1740 serves to isolate the individual blower modules, allowing them to be stacked together while maintaining electrical isolation. This design feature enables the creation of multi-stage blowers, potentially increasing the overall airflow and pressure capabilities of the system.

An epoxy layer 1750 may be used to secure and insulate various components of the thin strip ionic air movement blower 1710. This layer serves multiple purposes, including providing structural integrity to the thin strip ionic air movement blower 1710, ensuring proper positioning of the electrodes, and preventing electrical arcing between components. The use of epoxy contributes to the overall reliability and longevity of the device, particularly important in the compact and often challenging environment of a laptop.

This modular blower 1700 offers several advantages for laptop thermal management. The thin profile and stackable nature of the modular blower 1700 allow for integration into areas where traditional fans cannot fit, potentially enabling more efficient use of internal space in laptops. The modular approach provides flexibility in cooling system design, allowing manufacturers to adjust the number of blower modules based on the specific cooling requirements of different laptop models. Additionally, the silent operation of this technology improves user experience, especially in noise-sensitive environments.

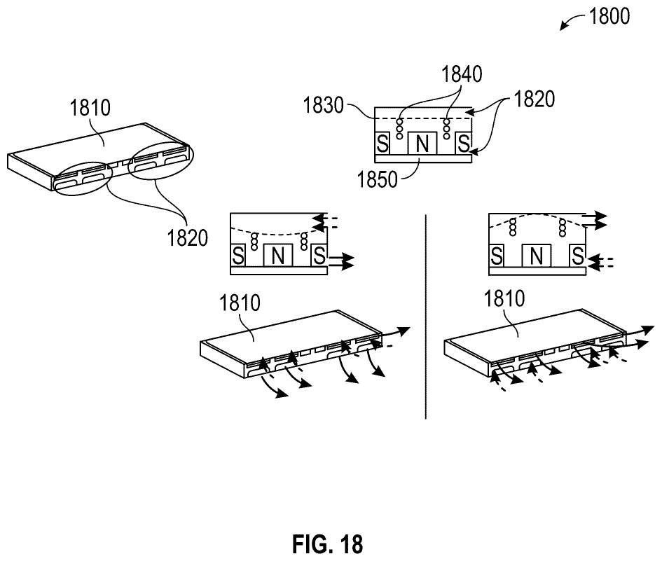

FIG. 18 shows modular electromagnetic (EM) blower system 1800, according to an embodiment. FIG. 18 illustrates an improved approach to air movement in laptop cooling systems, using EM principles to create a compact and efficient cooling solution.

The EM cooling jet module 1810 operates on electromagnetic principles, similar to those used in speakers, but optimized for air movement rather than sound production. The EM cooling jet module 1810 includes a diaphragm assembly 1830 that oscillates to create airflow. This design allows for silent operation and potentially lower power consumption compared to traditional fan-based cooling solutions.

Multiple inlets and outlets 1820 may be positioned above and below a plane of the diaphragm assembly 1830. This configuration creates a multi-directional airflow synchronized with the movement of the diaphragm assembly 1830. The placement of these multiple inlets and outlets 1820 allows for efficient air intake and exhaust, improving or maximizing the cooling performance of the module. This design feature enables the module to create airflow during both the upward and downward strokes of the diaphragm assembly 1830, potentially doubling the effective cooling capacity compared to single-direction designs.

Coil windings 1840 (e.g., copper coil windings) are attached to the diaphragm assembly 1830. When an alternating current is applied to the coil windings 1840, the coil windings 1840 interact with the magnetic field created by the permanent magnets 1850, causing the diaphragm assembly 1830 to oscillate. The design of these coil windings 1840, including factors such as the number of turns and wire gauge, may be selected to improve the performance and efficiency of the cooling module.

Multiple inlets and outlets 1820 in the EM cooling jet module 1810 allow for air intake and exhaust. These multiple inlets and outlets 1820 may be positioned to create a low-resistance airflow path for effectively using the low-pressure characteristics of the blower system 1800. The size and shape of these multiple inlets and outlets 1820 may be optimized to balance airflow volume with noise reduction.

Permanent magnets 1850 are positioned within the module to create a strong, stable magnetic field. These permanent magnets 1850 interact with the coil windings 1840 to cause the movement of the diaphragm assembly 1830. The permanent magnets 1850 may include high-strength magnets (e.g., neodymium), which provide for a compact design while maintaining efficient operation. The arrangement of these permanent magnets 1850 may be selected to create the alternating magnetic field for the oscillation of the diaphragm assembly 1830.

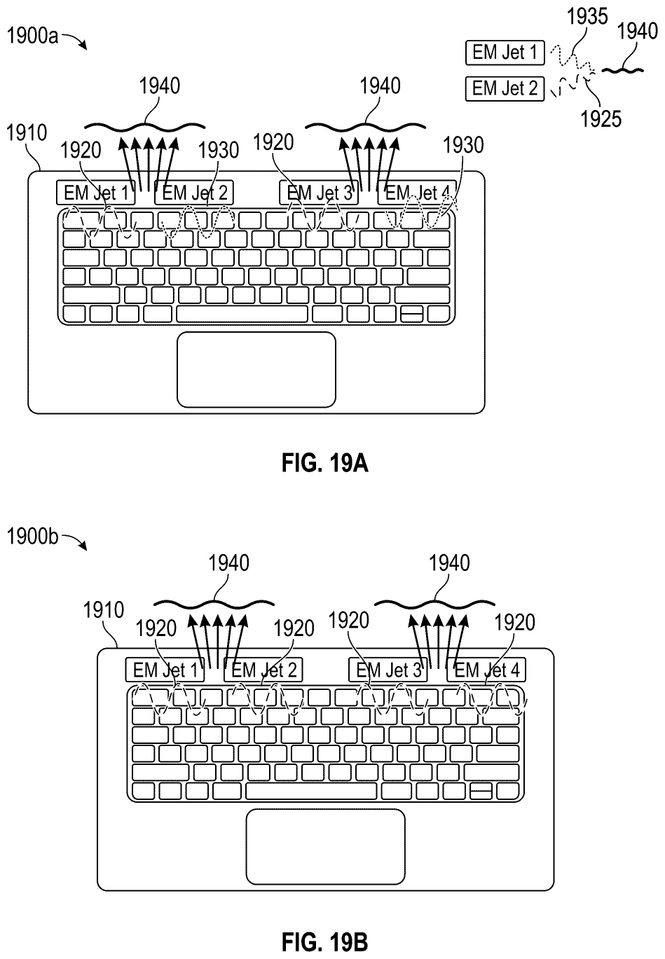

FIGS. 19A-19B show views of laptop keyboard, according to an embodiment. These figures illustrate an improved approach to thermal management and noise reduction in laptops, using EM jet modules in combination with a noise cancellation technique.

FIG. 19A shows a first cooling EM jet module implementation 1900a. The laptop keyboard 1910 may be equipped with multiple EM jet modules. These modules are designed to provide efficient cooling while maintaining a low acoustic profile. As shown in FIG. 19A The EM jet modules may be driven by out-of-phase input signals to implement a noise reduction technique. An in-phase signal 1920 may be applied to odd-numbered EM jet modules. This in-phase signal 1920 drives the diaphragm of these modules in a synchronized manner, creating a first soundwave pattern 1925. Simultaneously, an opposite-phase signal 1930 may be applied to even-numbered EM jet modules, creating a second soundwave pattern 1935 opposite from the first soundwave pattern 1925. Because the first soundwave pattern 1925 is opposite from the second soundwave pattern 1935, the amplitude of the combined soundwave 1940 is substantially smaller than then amplitude of the first soundwave pattern 1925 and the second soundwave pattern 1935, which reduces or eliminates any apparent noise generated by first cooling EM jet module implementation 1900a FIG. 19B shows a second cooling EM jet module implementation 1900b. In the second cooling EM jet module implementation 1900b, all EM jet modules receive in-phase signals, such as in-phase signal 1920. This configuration demonstrates the system's flexibility, allowing for different operational modes depending on cooling requirements and acoustic considerations.

The combined airflow pattern 1940 generated by the EM jet modules is represented in both figures. This airflow is created by the oscillation of the diaphragms within the EM jet modules, which operate on principles similar to those of speakers but optimized for air movement rather than sound production. The airflow pattern is designed to efficiently remove heat from processing components within the laptop, maintaining optimal operating temperatures.

This dual-purpose system, combining cooling and noise cancellation, offers several advantages for laptop thermal management. The use of EM jet modules allows for efficient cooling in a compact form factor, potentially enabling thinner laptop designs. The noise cancellation technique, achieved through the strategic phasing of EM jet modules and the use of opposite phase signals, can reduce the overall acoustic output by 5-6 dBA compared to traditional cooling solutions. This significant noise reduction contributes to an improved user experience, especially in noise-sensitive environments, while still maintaining effective cooling performance.

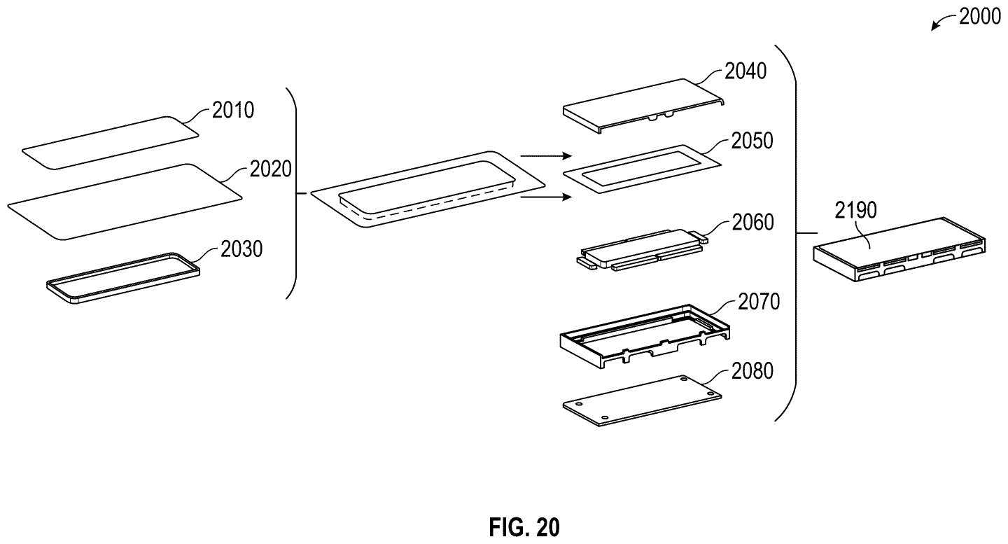

FIG. 20 shows EM jet air mover device assembly 2000, according to an embodiment. FIG. 20 illustrates the detailed components of an improved EM jet air mover designed for efficient and silent cooling in laptop systems.

The EM jet air mover device assembly 2000 includes a metal stiffener 2010 that provides structural integrity to the diaphragm 2020, ensuring that it maintains its shape during rapid oscillations. The stiffener 2010 is made of a lightweight yet rigid metal, such as aluminum or a thin steel alloy, to reduce or minimize the overall weight of the assembly while maximizing its durability and performance.

The diaphragm 2020 is a flexible component that oscillates to create airflow. The diaphragm 2020 may be made of a soft and light material, such as plastic or rubber, allowing for rapid and efficient movement. The design of the diaphragm 2020 may be optimized to displace a larger volume of air compared to traditional speaker drivers, improving the cooling capability of the EM jet air mover device assembly 2000.

A copper coil 2030 may be attached to the bottom side of the diaphragm 2020. It consists of multiple turns of thin copper wire, such as approximately ten turns of approximately 0.08 mm copper wire. When an alternating current is applied to this copper coil 2030, it interacts with the magnetic field created by permanent magnets, causing the diaphragm 2020 to oscillate and generate airflow.

The diaphragm assembly 2050 combines the coil 2030, stiffener 2010, and diaphragm 2020 into a single unit. This integrated design ensures synchronized movement of all components, maximizing the air displacement and, consequently, the cooling efficiency of the device.

A top plate 2040 forms the upper part of the EM jet air mover housing. The top plate 2040 may be lightweight yet durable, which contributes to the overall efficiency of the device while providing necessary protection to the internal components.

The magnets 2060 (e.g., neodymium magnets), are permanent magnets that create a magnetic field within the device. These magnets 2060 interact with the copper coil 2030 to generate the force necessary for movement of the diaphragm 2020. In an example, the use of high-strength neodymium magnets for the magnets 2060 allows for a compact design while maintaining efficient operation.

A plastic housing 2070 may be used to encase the EM jet air mover device assembly 2000. This plastic housing 2070 provides structural support, protects the internal components, and helps direct the airflow. This plastic housing 2070 may be formed from polycarbonate/acrylonitrile butadiene styrene (PC/ABS), which may contribute to the device's lightweight nature and potentially aids in noise reduction.

A bottom plate 2080 forms the base of the EM jet air mover. Its ferromagnetic properties complement the neodymium magnets, helping to shape and concentrate the magnetic field for optimal interaction with the copper coil. The steel plate also provides a stable foundation for the entire assembly.

The EM jet air mover 2090 represents the complete assembled device. This improved cooling solution may operate at a frequency range of 50-150 Hz, significantly lower than traditional audio frequencies. This low-frequency operation, combined with the encased design that prevents free air interaction, results in near-silent operation with noise levels close to 20 dBA.

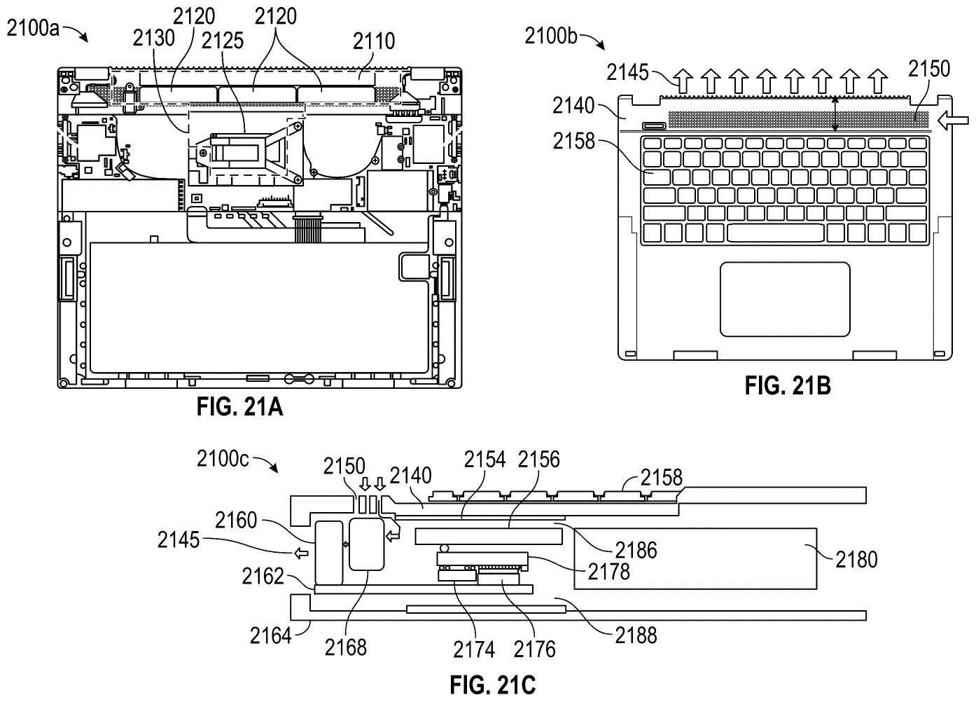

FIGS. 21A-21C show views of laptop cooling jet thermal solution, according to an embodiment. FIG. 21A shows a first view 2100a, FIG. 21B shows a second view 2100b, and FIG. 21C shows a third view 2100c. These figures illustrate an improved approach to thermal management in laptops, using electromagnetic (EM) air movers in combination with a low-impedance system design to improve cooling performance while maintaining a low profile.

The first view 2100a provides an overview of the laptop cooling jet thermal solution, including an outline of the laptop cooling solution components 2130. The laptop cooling solution components 2130 include a heat exchanger 2110, EM air movers 2120, and an SOC 2125. The heat exchanger 2110 may be positioned towards the rear of the laptop, efficiently dissipating heat generated by the SOC 2125. As shown in first view 2100a, the EM air movers 2120 are placed near the heat exchanger 2110, leveraging its low-pressure, high-flow characteristics to move air through the system.

The second view 2100b shows a top-town view of the laptop body. The second view 2100b shows the C-cover 2140 and the exhaust 2145 at the rear of the laptop chassis. Inlet vents 2150 may be positioned on the C-cover 2140 above the keyboard 2158 to allow cool air to enter the system.

The third view 2100c provides a detailed a cross-sectional perspective of various internal components and their arrangement. Similar to second view 2100b, third view 2100c shows C-cover 2140 and the exhaust 2145 at the rear of the laptop chassis, and inlet vents 2150 positioned on the C-cover 2140 above the keyboard 2158 to allow cool air to enter the system. A graphite layer 2154 may be used to improve heat spreading.

Heat-generating components may include a main PCB 2178, a PCB-mounted chipset 2174, and a secondary PCB 2156. The main PCB 2178 may be coupled to a thermally conductive PCB pedestal 2176 mounted on a thermally conductive substrate 2162. A heat exchanger 2160 may be connected to the thermally conductive substrate 2162, efficiently transferring heat from the system components to the air flow generated by the low-pressure EM air movers 2168.

The D-cover 2164 forms the base of the laptop, with the low-pressure EM air movers 2168 positioned to draw air through the system. An upper airgap 2186 and a lower airgap 2188 may provide airflow through the system, such as past a battery 2180 and past the various PCB components. The upper airgap 2186 and lower airgap 2188 provide a path of reduced airflow resistance, allowing the low-pressure EM air movers 2168 to operate efficiently. The C-cover inlet design, coupled with upper airgap 2186 and lower airgap 2188, creates a direct and short path for air to enter the system, flow over the heat-generating components, and exit through the rear exhaust.

This improved cooling system design shown in FIGS. 21A-21C provides higher cooling capabilities in thin and light systems while maintaining low acoustic levels. By using EM air movers within a low-impedance system design, the improved cooling system design addresses the challenge of delivering increased performance in devices with reduced thickness. The silent operation of the EM air movers, combined with their compact size, contributes to improved user experience and potentially enables more efficient use of internal space compared to traditional cooling designs.

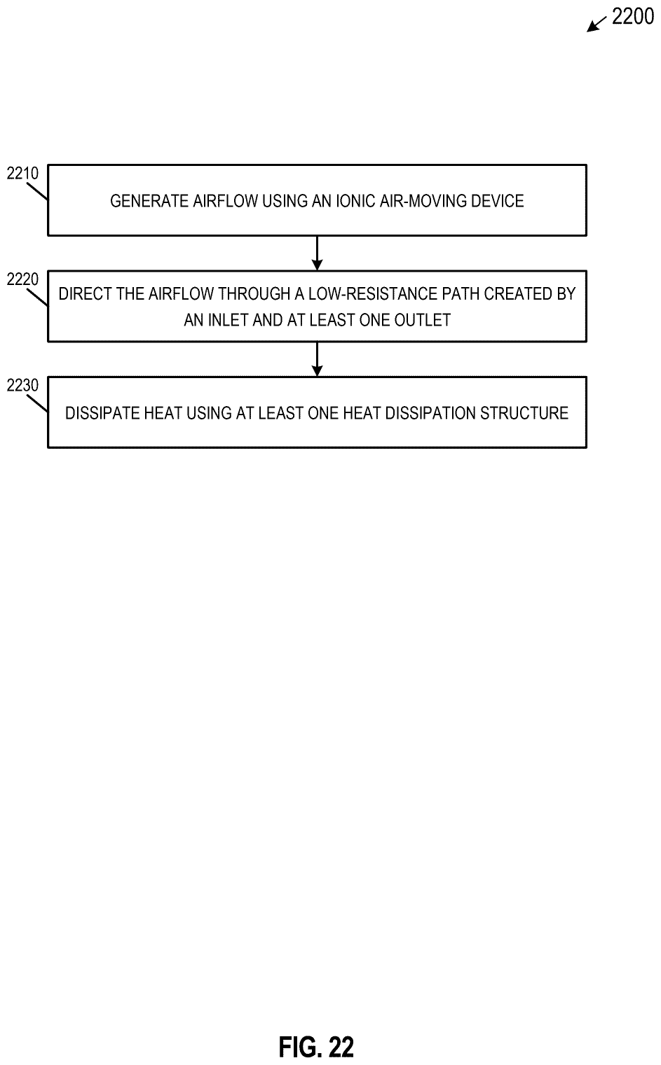

FIG. 22 is a flow diagram illustrating a method 2200 for cooling a computing device, according to an embodiment. At step 2210, method 2200 includes generating airflow using an ionic air-moving device. At step 2210, method 2200 includes directing the airflow through a low-resistance path created by an inlet and at least one outlet. At step 2230, method 2200 includes dissipating heat using at least one heat dissipation structure.

The ionic air-moving device may include an alternating current (AC) ionic air-moving device. The AC ionic air-moving device may include an exposed electrode in direct contact with air and an embedded electrode separated from air by a dielectric material. The ionic air-moving device may be configured to receive AC current and generate an electric field to ionize air molecules near the exposed electrode and move ionized air particles toward the embedded electrode.

Method 2200 may further include maintaining noise levels below a predetermined threshold during operation of the ionic air-moving device. The predetermined threshold may be 17 dBA or less. The computing device may have a base thickness of 10 mm or less. The ionic air-moving device may include a low-pressure blower.

Method 2200 may further include arranging the low-pressure blower in a modular configuration. The modular configuration may include multiple blower modules arranged in at least one of a series configuration, a parallel configuration, or a combination series and parallel configuration. Method 2200 may further include maintaining a system impedance below a specified value.

Method 2200 may further include using a thin-film ionic air-moving device with a thickness between 0.25 mm and 0.5 mm. Method 2200 may further include integrating the thin-film ionic air-moving device into an air gap of the computing device. Method 2200 may further include using the thin-film ionic air-moving device for targeted cooling of specific areas within the computing device.

Method 2200 may further include selectively activating at least one centrifugal blower. Method 2200 may further include selectively operating the ionic air-moving device and the centrifugal blower based on cooling demands.

The ionic air-moving device may include an electrode configuration with only one exposed electrode.

Method 2200 may further include placing the inlet on a C-cover of the computing device. The heat dissipation structure may include a heat exchanger spanning substantially across a computing device width.

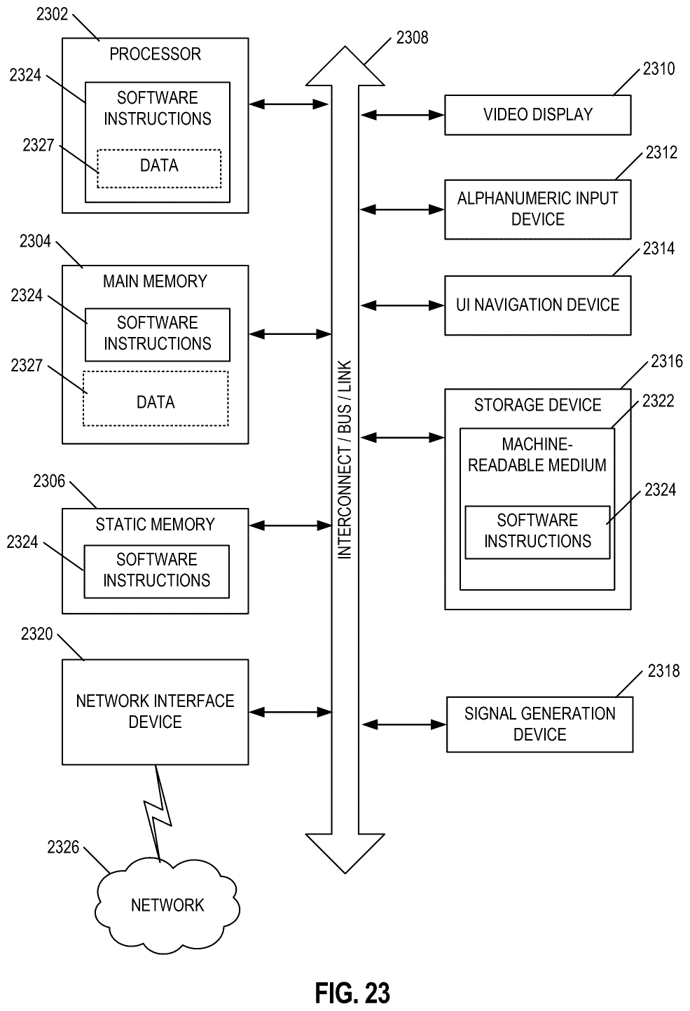

FIG. 23 is a block diagram illustrating a machine in the example form of a computer system 2300. The computer system 2300 may use one or more of the electronic device cooling solutions described herein. The computer system 2300 may also include a set or sequence of instructions that may be executed to cause the machine to perform any one of the methodologies discussed herein. In alternative embodiments, the machine operates as a standalone device or may be connected (e.g., networked) to other machines. In a networked deployment, the machine may operate in the capacity of either a server or a client machine in server-client network environments, or it may act as a peer machine in peer-to-peer (or distributed) network environments. The machine may be a vehicle subsystem, a personal computer (PC), a tablet PC, a hybrid tablet, a smartphone or other mobile telephone, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein. Similarly, the term “processor-based system” shall be taken to include any set of one or more machines that are controlled by or operated by a processor (e.g., a computer) to individually or jointly execute instructions to perform any one or more of the methodologies discussed herein.

Example computer system 2300 includes at least one processor 2302 (e.g., a central processing unit (CPU), a graphics processing unit (GPU) or both, processor cores, compute nodes, etc.), a main memory 2304 and a static memory 2306, which communicate with each other via a link 2308 (e.g., interconnect or bus). The computer system 2300 may further include a video display unit 2310, an alphanumeric input device 2312 (e.g., a keyboard), and a user interface (UI) navigation device 2314 (e.g., a mouse). In one aspect, the video display unit 2310, input device 2312 and UI navigation device 2314 are incorporated into a touch screen display. The computer system 2300 may additionally include a storage device 2316 (e.g., a drive unit), a signal generation device 2318 (e.g., a speaker), a network interface device 2320, and one or more sensors (not shown), such as a global positioning system (GPS) sensor, compass, accelerometer, mems gyroscope, magnetometer, or another location, motion, or orientation sensor.

The storage device 2316 includes a machine-readable medium 2322 on which is stored one or more sets of data structures and instructions 2324 (e.g., software) embodying or utilized by any one or more of the methodologies or functions described herein. The instructions 2324 may also reside, completely or at least partially, within the main memory 2304, static memory 2306, and/or within the processor 2302 during execution thereof by the computer system 2300, with the main memory 2304, static memory 2306, and the processor 2302 also constituting machine-readable media. As an example, the software instructions 2324 may include instructions to implement and execute the segmentation operations via the processor (e.g., with software as configured and operated in the examples above). As a further example, the main memory 2304 (or the other memory or storage such as the static memory 2306, or the storage device 2316) may host various data 2327 used with the video processing operations discussed herein.

While the machine-readable medium 2322 is illustrated in an example aspect to be a single medium, the term “machine-readable medium” may include a single medium or multiple media (e.g., a centralized or distributed database, and/or associated caches and servers) that store the one or more instructions 2324. The term “machine-readable medium” shall also be taken to include any tangible medium that is capable of storing, encoding or carrying instructions for execution by the machine and that cause the machine to perform any one or more of the methodologies of the present disclosure or that is capable of storing, encoding or carrying data structures utilized by or associated with such instructions. The term “machine-readable medium” shall accordingly be taken to include, but not be limited to, solid-state memories, and optical and magnetic media. Specific examples of machine-readable media include non-volatile memory, including but not limited to, by way of example, semiconductor memory devices (e.g., electrically programmable read-only memory (EPROM), electrically erasable programmable read-only memory (EEPROM)) and flash memory devices; magnetic disks such as internal hard disks and removable disks; magneto-optical disks; and CD-ROM and DVD-ROM disks.

The instructions 2324 may further be transmitted or received over a communications network 2326 using a transmission medium via the network interface device 2320 using any one of a number of well-known transfer protocols (e.g., HTTP). Examples of communication networks include a local area network (LAN), a wide area network (WAN), the Internet, mobile telephone networks, plain old telephone (POTS) networks, and wireless data networks (e.g., Bluetooth, Wi-Fi, 3G, and 4G LTE/LTE-A, 5G, 6G, DSRC, or satellite communication networks). The term “transmission medium” shall be taken to include any intangible medium that is capable of storing, encoding, or carrying instructions for execution by the machine, and includes digital or analog communications signals or other intangible medium to facilitate communication of such software.

The above detailed description includes references to the accompanying drawings, which form a part of the detailed description. The drawings show, by way of illustration, specific embodiments that may be practiced. These embodiments are also referred to herein as “examples.” Such examples may include elements in addition to those shown or described. However, also contemplated are examples that include the elements shown or described. Moreover, also contemplated are examples using any combination or permutation of those elements shown or described (or one or more aspects thereof), either with respect to a particular example (or one or more aspects thereof), or with respect to other examples (or one or more aspects thereof) shown or described herein.

Additional examples of the presently described embodiments include the following, non-limiting implementations. Each of the following non-limiting examples may stand on its own or may be combined in any permutation or combination with any one or more of the other examples provided below or throughout the present disclosure.

Example 1 is a cooling system for a computing device, comprising: a computing device housing; a heat dissipation structure within the computing device housing, the heat dissipation structure configured to absorb heat from a processing device; an ionic air-moving device configured to generate airflow across the heat dissipation structure to direct heat from the processing device computing out of the computing device housing.

In Example 2, the subject matter of Example 1 includes wherein the ionic air-moving device includes an alternating current (AC) ionic air-moving device, the AC ionic air-moving device including: an exposed electrode in direct contact with air; and an embedded electrode separated from air by a dielectric material.

In Example 3, the subject matter of Example 2 includes wherein the ionic air-moving device is configured to: receive AC current; and generate an electric field to ionize air molecules near the exposed electrode and move ionized air particles toward the embedded electrode.

In Example 4, the subject matter of Examples 1-3 includes wherein the ionic air-moving device is configured to maintain noise levels below a predetermined threshold during operation.

In Example 5, the subject matter of Example 4 includes wherein the predetermined threshold is 20 dBA or less.

In Example 6, the subject matter of Examples 1-5 includes wherein the computing device has a base thickness of 10 mm or less.

In Example 7, the subject matter of Examples 1-6 includes wherein the ionic air-moving device includes a plurality of low-pressure blowers.

In Example 8, the subject matter of Example 7 includes wherein the plurality of low-pressure blowers are arranged in a modular configuration.

In Example 9, the subject matter of Example 8 includes wherein the modular configuration includes multiple blower modules arranged in a series configuration, a parallel configuration, or a combination of series and parallel configuration.

In Example 10, the subject matter of Examples 1-9 includes, an airflow path within the computing device housing, the airflow path including an inlet port and an outlet port, the inlet port separated from the outlet port.

In Example 11, the subject matter of Example 10 includes wherein the airflow path maintains a system impedance below a specified value.

In Example 12, the subject matter of Examples 1-11 includes, a thin-film air-moving device.

In Example 13, the subject matter of Example 12 includes, the thin-film air-moving device having an associated thickness between 0.25 mm and 0.5 mm.

In Example 14, the subject matter of Examples 12-13 includes wherein the thin-film air-moving device is integrated into an air gap of the computing device.

In Example 15, the subject matter of Examples 12-14 includes wherein the thin-film air-moving device is configured for targeted cooling of specific areas within the computing device.

In Example 16, the subject matter of Examples 1-15 includes, a centrifugal blower.

In Example 17, the subject matter of Example 16 includes wherein the ionic air-moving device and the centrifugal blower are operated selectively based on cooling demands.

In Example 18, the subject matter of Examples 1-17 includes wherein the ionic air-moving device includes an electrode configuration with only one exposed electrode.

In Example 19, the subject matter of Examples 1-18 includes wherein the inlet port is located on a C-cover of the computing device.

In Example 20, the subject matter of Examples 1-19 includes wherein the heat dissipation structure includes a heat exchanger spanning substantially across a computing device width.

Example 21 is a method for cooling a computing device, comprising: absorbing heat from a processing device at a heat dissipation structure, the processing device and heat dissipation structure disposed within a computing device housing; and generating airflow at an ionic air-moving device, the airflow directed through an airflow path and across the heat dissipation structure to direct heat from the processing device computing out of the computing device housing.

In Example 22, the subject matter of Example 21 includes wherein the ionic air-moving device includes an alternating current (AC) ionic air-moving device, the AC ionic air-moving device including an exposed electrode in direct contact with air and an embedded electrode separated from air by a dielectric material.

In Example 23, the subject matter of Example 22 includes wherein the ionic air-moving device is configured to: receive an AC current; and generate an electric field to ionize air molecules near the exposed electrode and move ionized air particles toward the embedded electrode.

In Example 24, the subject matter of Examples 21-23 includes, maintaining noise levels below a predetermined threshold during operation of the ionic air-moving device.

In Example 25, the subject matter of Example 24 includes wherein the predetermined threshold is 20 dBA or less.

In Example 26, the subject matter of Examples 21-25 includes wherein the computing device has a base thickness of 10 mm or less.

In Example 27, the subject matter of Examples 21-26 includes wherein the ionic air-moving device includes a plurality of low-pressure blowers.

In Example 28, the subject matter of Example 27 includes, arranging the plurality of low-pressure blowers in a modular configuration.

In Example 29, the subject matter of Example 28 includes wherein the modular configuration includes multiple blower modules arranged in a series configuration, a parallel configuration, or a combination of series and parallel configuration.

In Example 30, the subject matter of Examples 21-29 includes, maintaining a system impedance below a specified value.

In Example 31, the subject matter of Examples 21-30 includes wherein the computing device includes a thin-film ionic air-moving device.

In Example 32, the subject matter of Example 31 includes wherein the thin-film ionic air-moving device has an associated thickness between 0.25 mm and 0.5 mm.

In Example 33, the subject matter of Examples 31-32 includes wherein the thin-film ionic air-moving device is disposed in an air gap of the computing device.

In Example 34, the subject matter of Examples 31-33 includes, targeting the thin-film ionic air-moving device for targeted cooling of a predetermined area within the computing device.

In Example 35, the subject matter of Examples 21-34 includes, selectively activating a centrifugal blower.

In Example 36, the subject matter of Example 35 includes, selectively operating the ionic air-moving device and the centrifugal blower based on cooling demands.

In Example 37, the subject matter of Examples 21-36 includes wherein the ionic air-moving device includes an electrode configuration with only one exposed electrode.

In Example 38, the subject matter of Examples 21-37 includes, disposing an airflow inlet port on a C-cover of the computing device.

In Example 39, the subject matter of Examples 21-38 includes wherein the heat dissipation structure includes a heat exchanger spanning substantially across a computing device width.

Example 40 is an apparatus comprising: means for absorbing heat from a processing device at a heat dissipation structure, the processing device and heat dissipation structure disposed within a computing device housing; and means for generating airflow at an ionic air-moving device, the airflow directed through an airflow path and across the heat dissipation structure to direct heat from the processing device computing out of the computing device housing.

In Example 41, the subject matter of Example 40 includes wherein the ionic air-moving device includes an alternating current (AC) ionic air-moving device, the AC ionic air-moving device including an exposed electrode in direct contact with air and an embedded electrode separated from air by a dielectric material.

In Example 42, the subject matter of Example 41 includes wherein the ionic air-moving device is configured to: receive an AC current; and generate an electric field to ionize air molecules near the exposed electrode and move ionized air particles toward the embedded electrode.

In Example 43, the subject matter of Examples 40-42 includes, means for maintaining noise levels below a predetermined threshold during operation of the ionic air-moving device.

In Example 44, the subject matter of Example 43 includes wherein the predetermined threshold is 20 dBA or less.

In Example 45, the subject matter of Examples 40-44 includes wherein the ionic air-moving device includes a plurality of low-pressure blowers.

In Example 46, the subject matter of Example 45 includes, means for arranging the plurality of low-pressure blowers in a modular configuration.

In Example 47, the subject matter of Example 46 includes wherein the modular configuration includes multiple blower modules arranged in a series configuration, a parallel configuration, or a combination of series and parallel configuration.

In Example 48, the subject matter of Examples 40-47 includes, means for maintaining a system impedance below a specified value.

In Example 49, the subject matter of Examples 40-48 includes wherein the ionic air-moving device includes a thin-film ionic air-moving device.

In Example 50, the subject matter of Example 49 includes wherein the thin-film ionic air-moving device has an associated thickness between 0.25 mm and 0.5 mm.

In Example 51, the subject matter of Examples 49-50 includes wherein the thin-film ionic air-moving device is disposed in an air gap.

In Example 52, the subject matter of Examples 49-51 includes, means for targeting the thin-film ionic air-moving device for targeted cooling of a predetermined area.

In Example 53, the subject matter of Examples 40-52 includes, means for selectively activating a centrifugal blower.

In Example 54, the subject matter of Example 53 includes, means for selectively operating the ionic air-moving device and the centrifugal blower based on cooling demands.

In Example 55, the subject matter of Examples 40-54 includes wherein the ionic air-moving device includes an electrode configuration with only one exposed electrode.

In Example 56, the subject matter of Examples 40-55 includes, means for disposing an airflow inlet port on a C-cover.

In Example 57, the subject matter of Examples 40-56 includes wherein the heat dissipation structure includes a heat exchanger spanning substantially across a computing device width.

Example 58 is an air mover for cooling electronic devices, comprising: a computing device housing; a heat dissipation structure within the computing device housing, the heat dissipation structure configured to absorb heat from a processing device; a flexible membrane air-moving device; and an actuator configured to oscillate the flexible membrane air-moving device to generate airflow across the heat dissipation structure to direct heat from the processing device computing out of the computing device housing.

In Example 59, the subject matter of Example 58 includes, an electromagnetic field source generating a field to interact with the actuator.

In Example 60, the subject matter of Examples 58-59 includes wherein the actuator includes at least one of an electromagnetic coil or a piezoelectric actuator.

In Example 61, the subject matter of Examples 58-60 includes wherein a flexible membrane of the flexible membrane air-moving device is configured to oscillate at a frequency between 20 Hz and 200 Hz.

In Example 62, the subject matter of Examples 58-61 includes wherein the actuator is configured to generate airflow while maintaining a noise level below a predetermined noise threshold.

In Example 63, the subject matter of Examples 58-62 includes, an airflow path within the computing device housing, the airflow path including an inlet port and an outlet port.

In Example 64, the subject matter of Example 63 includes wherein the inlet port is physically separated from the outlet port.

In Example 65, the subject matter of Examples 58-64 includes wherein the flexible membrane air-moving device is configured as a modular unit capable of being used individually or in combination with multiple units.

In Example 66, the subject matter of Examples 58-65 includes, an active noise cancellation system, the active noise cancellation system configured to phase-shift control signals between air mover units.

In Example 67, the subject matter of Examples 58-66 includes wherein the flexible membrane air-moving device is configured for use in at least one of an evacuative flow architecture or a hyperbaric flow architecture.

In Example 68, the subject matter of Examples 58-67 includes wherein the flexible membrane air-moving device includes a diaphragm assembly, the diaphragm assembly including a metal stiffener and a polymer diaphragm.

In Example 69, the subject matter of Examples 58-68 includes wherein the flexible membrane air-moving device is configured to provide cooling for processors with thermal design power (TDP) between 15 W and 20 W while consuming less than 1 W of power.

In Example 70, the subject matter of Examples 58-69 includes wherein the actuator includes a copper coil attached to the flexible membrane.

In Example 71, the subject matter of Examples 59-70 includes wherein the electromagnetic field source includes permanent magnets generating a magnetic field.

In Example 72, the subject matter of Examples 58-71 includes wherein a flexible membrane within the flexible membrane air-moving device is configured to move between a first position and a second position to create pressure differentials within the computing device housing.

Example 73 is a method of cooling an electronic device, comprising: absorbing heat from a processing device at a heat dissipation structure, the processing device and heat dissipation structure disposed within a computing device housing; generating airflow at a flexible membrane air-moving device, the flexible membrane air-moving device including a flexible membrane and an actuator configured to oscillate the flexible membrane, the flexible membrane configured to generate the airflow across the heat dissipation structure to direct heat from the processing device computing out of the computing device housing.

In Example 74, the subject matter of Example 73 includes wherein oscillating the flexible membrane includes operating the actuator at a frequency between 20 Hz and 200 Hz.

In Example 75, the subject matter of Examples 73-74 includes wherein a number of air-moving devices is selected to provide a predetermined cooling capacity.

In Example 76, the subject matter of Example 75 includes, implementing active noise cancellation by operating adjacent air mover units with a phase-shifted signal.

In Example 77, the subject matter of Example 76 includes wherein the phase-shifted signal includes an opposite phase signal.

In Example 78, the subject matter of Examples 73-77 includes wherein: the computing device housing includes an inlet port and an outlet port; and generating airflow includes drawing cool air through the inlet port and expelling warm air through the outlet port.

In Example 79, the subject matter of Examples 73-78 includes wherein the actuator is configured to generate airflow while maintaining a noise level below a predetermined noise threshold.

In Example 80, the subject matter of Examples 73-79 includes wherein the flexible membrane air-moving device includes at least one of a flexible membrane air-moving evacuative flow architecture or a flexible membrane air-moving hyperbaric flow architecture.

In Example 81, the subject matter of Examples 73-80 includes wherein the actuator includes at least one of an electromagnetic coil or a piezoelectric material.

In Example 82, the subject matter of Examples 73-81 includes, integrating the flexible membrane air-moving device with existing components of the electronic device.

In Example 83, the subject matter of Examples 73-82 includes wherein the flexible membrane includes a diaphragm assembly, the diaphragm assembly including a metal stiffener and a polymer diaphragm.

In Example 84, the subject matter of Examples 73-83 includes, providing cooling for processors with thermal design power (TDP) between 15W and 20W while consuming less than 1 W of power.

In Example 85, the subject matter of Examples 73-84 includes wherein oscillating the flexible membrane includes moving the membrane between a first position and a second position to create a pressure differential within the housing.

In Example 86, the subject matter of Examples 73-85 includes, generating an electromagnetic field to interact with the actuator using an electromagnetic field source.

In Example 87, the subject matter of Example 86 includes wherein the electromagnetic field source includes permanent magnets generating a magnetic field.

In Example 88, the subject matter of Examples 73-87 includes wherein the computing device housing has a thickness of less than 4 mm.

Example 89 is an apparatus comprising: means for absorbing heat from a processing device at a heat dissipation structure, the processing device and heat dissipation structure disposed within a computing device housing; means for generating airflow at a flexible membrane air-moving device, the flexible membrane air-moving device including a flexible membrane and an actuator configured to oscillate the flexible membrane, the flexible membrane configured to generate the airflow across the heat dissipation structure to direct heat from the processing device computing out of the computing device housing.

In Example 90, the subject matter of Example 89 includes wherein oscillating the flexible membrane includes operating the actuator at a frequency between 20 Hz and 200 Hz.

In Example 91, the subject matter of Examples 89-90 includes wherein a number of air-moving devices is selected to provide a predetermined cooling capacity.

In Example 92, the subject matter of Example 91 includes, means for implementing active noise cancellation by operating adjacent air mover units with a phase-shifted signal.

In Example 93, the subject matter of Example 92 includes wherein the phase-shifted signal includes an opposite phase signal.

In Example 94, the subject matter of Examples 89-93 includes wherein: the computing device housing includes an inlet port and an outlet port; and generating airflow includes drawing cool air through the inlet port and expelling warm air through the outlet port.

In Example 95, the subject matter of Examples 89-94 includes wherein the actuator is configured to generate airflow while maintaining a noise level below a predetermined noise threshold.

In Example 96, the subject matter of Examples 89-95 includes wherein the flexible membrane air-moving device includes at least one of a flexible membrane air-moving evacuative flow architecture or a flexible membrane air-moving hyperbaric flow architecture.

In Example 97, the subject matter of Examples 89-96 includes wherein the actuator includes at least one of an electromagnetic coil or a piezoelectric material.

In Example 98, the subject matter of Examples 89-97 includes, means for integrating the flexible membrane air-moving device with existing components of the computing device housing.

In Example 99, the subject matter of Examples 89-98 includes wherein the flexible membrane includes a diaphragm assembly, the diaphragm assembly including a metal stiffener and a polymer diaphragm.

In Example 100, the subject matter of Examples 89-99 includes, means for providing cooling for processors with thermal design power (TDP) between 15 W and 20 W while consuming less than 1 W of power.

In Example 101, the subject matter of Examples 89-100 includes wherein oscillating the flexible membrane includes moving the membrane between a first position and a second position to create a pressure differential within the housing.

In Example 102, the subject matter of Examples 89-101 includes, means for generating an electromagnetic field to interact with the actuator using an electromagnetic field source.

In Example 103, the subject matter of Example 102 includes wherein the field source includes permanent magnets generating a magnetic field.

In Example 104, the subject matter of Examples 89-103 includes wherein the housing has a thickness of less than 4 mm.

Example 105 is a mobile computing device comprising: an air mover comprising: an air mover housing; a flexible membrane disposed within the air mover housing; an actuator configured to oscillate the flexible membrane; and an inlet port and an outlet port in the air mover housing; wherein the air mover is configured to generate airflow through the inlet port and outlet port to cool a mobile computing device processor while maintaining noise levels below a predetermined threshold.

In Example 106, the subject matter of Example 105 includes wherein the air mover further includes an electromagnetic field source generating a field to interact with the actuator.

In Example 107, the subject matter of Examples 105-106 includes wherein the actuator includes at least one of an electromagnetic coil or a piezoelectric material.

In Example 108, the subject matter of Examples 105-107 includes wherein the flexible membrane is configured to oscillate at a frequency between 20 Hz and 200 Hz.

In Example 109, the subject matter of Examples 105-108 includes wherein the inlet port is physically separated from the outlet port.

In Example 110, the subject matter of Examples 105-109 includes, multiple air movers configured to operate in combination to achieve a desired cooling capacity.

In Example 111, the subject matter of Example 110 includes, an active noise cancellation system using phase-shifted signals between adjacent air movers.

In Example 112, the subject matter of Examples 105-111 includes wherein the air mover housing has a thickness of less than 4 mm.

In Example 113, the subject matter of Examples 105-112 includes wherein the air mover is adaptable for use in at least one of an evacuative airflow architecture or a hyperbaric airflow architecture.

In Example 114, the subject matter of Examples 105-113 includes wherein the flexible membrane includes a diaphragm assembly including a metal stiffener and a polymer diaphragm.

In Example 115, the subject matter of Examples 105-114 includes wherein the air mover is configured to provide cooling for the mobile computing device processor with thermal design power (TDP) between 15 W and 20 W while consuming less than 1 W of power.

In Example 116, the subject matter of Examples 105-115 includes wherein the actuator includes a copper coil attached to the flexible membrane.

In Example 117, the subject matter of Examples 106-116 includes wherein the field source includes permanent magnets generating a magnetic field.

In Example 118, the subject matter of Examples 105-117 includes wherein the air mover is integrated with existing components of the mobile computing device.

Example 119 is at least one machine-readable medium including instructions that, when executed by processing circuitry, cause the processing circuitry to perform operations to implement of any of Examples 1-118.

Example 120 is an apparatus comprising means to implement of any of Examples 1-118.

Example 121 is a system to implement of any of Examples 1-118.

Example 122 is a method to implement of any of Examples 1-118.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein.” Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to suggest a numerical order for their objects.

The above description is intended to be illustrative, and not restrictive. For example, the above-described examples (or one or more aspects thereof) may be used in combination with others. Other embodiments may be used, such as by one of ordinary skill in the art upon reviewing the above description. The Abstract is to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. However, the claims may not set forth every feature disclosed herein as embodiments may feature a subset of said features. Further, embodiments may include fewer features than those disclosed in a particular example. Thus, the following claims are hereby incorporated into the Detailed Description, with a claim standing on its own as a separate aspect. The scope of the embodiments disclosed herein is to be determined with reference to the appended claims, along with the full scope of equivalents to which such claims are entitled.

What is claimed is:

1. A cooling system for a computing device, comprising:
a computing device housing;
a heat dissipation structure within the computing device housing, the heat dissipation structure configured to absorb heat from a processing device;
an ionic air-moving device configured to generate airflow across the heat dissipation structure to direct heat from the processing device computing out of the computing device housing.

2. The cooling system of claim 1, wherein the ionic air-moving device includes an alternating current (AC) ionic air-moving device, the AC ionic air-moving device including:
an exposed electrode in direct contact with air; and
an embedded electrode separated from air by a dielectric material.

3. The cooling system of claim 2, wherein the ionic air-moving device is configured to:
receive AC current; and
generate an electric field to ionize air molecules near the exposed electrode and move ionized air particles toward the embedded electrode.

4. The cooling system of claim 1, wherein the ionic air-moving device is configured to maintain noise levels below a predetermined threshold during operation.

5. The cooling system of claim 1, wherein the ionic air-moving device includes a plurality of low-pressure blowers.

6. The cooling system of claim 5, wherein the plurality of low-pressure blowers are arranged in a modular configuration.

7. The cooling system of claim 6, wherein the modular configuration includes multiple blower modules arranged in a series configuration, a parallel configuration, or a combination of series and parallel configuration.

8. The cooling system of claim 1, further including a thin-film air-moving device.

9. The cooling system of claim 1, further including a centrifugal blower.

10. The cooling system of claim 9, wherein the ionic air-moving device and the centrifugal blower are operated selectively based on cooling demands.

11. An apparatus comprising:
means for absorbing heat from a processing device at a heat dissipation structure, the processing device and heat dissipation structure disposed within a computing device housing; and
means for generating airflow at an ionic air-moving device, the airflow directed through an airflow path and across the heat dissipation structure to direct heat from the processing device computing out of the computing device housing.

12. The apparatus of claim 11, wherein the ionic air-moving device includes an alternating current (AC) ionic air-moving device, the AC ionic air-moving device including an exposed electrode in direct contact with air and an embedded electrode separated from air by a dielectric material.

13. The apparatus of claim 12, wherein the ionic air-moving device is configured to:
receive an AC current; and
generate an electric field to ionize air molecules near the exposed electrode and move ionized air particles toward the embedded electrode.

14. The apparatus of claim 11, further including means for maintaining noise levels below a predetermined threshold during operation of the ionic air-moving device.

15. The apparatus of claim 11, wherein the ionic air-moving device includes a thin-film ionic air-moving device.

16. The apparatus of claim 11, further including means for selectively activating a centrifugal blower.

17. The apparatus of claim 16, further including means for selectively operating the ionic air-moving device and the centrifugal blower based on cooling demands.

18. An air mover for cooling electronic devices, comprising:
a computing device housing;
a heat dissipation structure within the computing device housing, the heat dissipation structure configured to absorb heat from a processing device;
a flexible membrane air-moving device; and
an actuator configured to oscillate the flexible membrane air-moving device to generate airflow across the heat dissipation structure to direct heat from the processing device computing out of the computing device housing.

19. The air mover of claim 18, further including an electromagnetic field source generating a field to interact with the actuator.

20. The air mover of claim 18, further including an active noise cancellation system, the active noise cancellation system configured to phase-shift control signals between air mover units.
